(19) United States
(12) Patent Application Publication
(10) Pub. No.: US 2010/0015550 A1
(43) Pub. Date: Jan. 21, 2010

(54) DUAL DAMASCENE VIA FILLING COMPOSITION

(76) Inventors: Weihong Liu, Bridgewater, NJ (US); Guanyang Lin, Whitehouse Station, NJ (US); Salem K. Mullen, Florham Park, NJ (US); Jian Yin, Bridgewater, NJ (US); Mark Neisser, Whitehouse Station, NJ (US)

Correspondence Address: ALAN P. KASS;AZ ELECTRONIC MATERIALS USA CORP., 70 MEISTER AVENUE, SOMERVILLE, NJ, 08876, US

(21) Appl. No.: 12/174,718

(22) Filed: Jul. 17, 2008

(51) Int. Cl. G03F 7/20; G03F 7/004

(52) U.S. Cl. 430/280.1; 430/270.1; 430/319

(57) ABSTRACT

Compositions for use in dual damascene process are disclosed.

### FIELD OF THE INVENTION

The present invention relates to fill material for use with vias in dual damascene processing.

### BACKGROUND OF THE INVENTION

Dual Damascene (DD) is a process employed in Integrated Circuit (IC) fabrication for forming interconnect structures of copper metal lines and columnar metal via connecting the lines in adjacent layers. There are two types of widely used DD processes in the art. One is the so-called Via-First approach and the other the Trench-First approach. In the Via-First approach, substrate is spin-coated with bottom antireflective coating (BARC) and photoresist. Lithographic processes generate via pattern in the photoresist film. A plasma etch step using resist pattern as a mask cuts through the BARC, cap layer and low k material (inter layer dielectric, ILD) down to etch stop to form via in the ILD. Photoresist and BARC are then stripped. The second BARC coating will not only form a thin film on surface of the substrate but also fully fill the preformed via in the ILD. A photoresist trench pattern is generated by another photolithographic step and similarly transferred into ILD by a plasma etching process. During the second etch process, BARC material should not be completely removed. The material on bottom of via prevents the etch stop layer from being broken through to expose the underlying copper line to reactive etch plasma. Photoresist and BARC are then stripped either through dry (plasma) or wet etch chemistry. A special soft low energy plasma etch is applied to open the etch stop. Bulk copper is then deposited into the structure by an electroplating process. Excess copper on surface of the substrate is removed by a Chemical Mechanic Planarization (CMP) process. A Chemical Vapor Deposition (CVD) process deposits a thin cap layer on substrate surface to cover the copper lines and finishes the DD process.

In the Trench-First approach, most of the process is similar to those aforementioned for the Via-First approach except for that the formation sequence of the two lithographic patterns are reversed. In the Trench-First approach, a trench pattern is formed by the first lithographic process instead of a via pattern. The trench is transferred into the ILD by a plasma etch step only to a desired depth. Photoresist and BARC materials are stripped, which is followed by a second lithographic process for generating a via pattern. Subsequent processes of etching (cut through the BARC and the ILD but stopping at the etch stop layer), photoresist and BARC stripping, soft etching (etch stop layer opening), copper plating, CMP and CVD generate the same DD structure as from the Via-First approach.

In a typical Dual Damascene process, BARC material can function well for both filling via/trench patterns generated in ILD and planarizing substrate to substrate reflectivity control. However, due to continual scaling of feature size in advanced IC devices, requirements for via/trench filling and reflectivity control need to be satisfied by two different materials, filling and BARC materials.

In advanced DD processes, preparation for a second lithographic process involves a via (Via-First) or trench (Trench-First) pattern filling using a filling material before BARC and photoresist coating. In general, the via or trench is overfilled to make sure all patterns in the substrate are covered. Excess filling material on top of the substrate is removed through either plasma etching or a CMP step before the BARC and resist coatings.

### SUMMARY OF THE INVENTION

The present invention relates to a novel gap fill material composition for via-filling comprising a polymer having at least one repeating unit of formula (3) and, optionally, one or more repeating units selected from formula (1), formula (2), and/or mixtures thereof

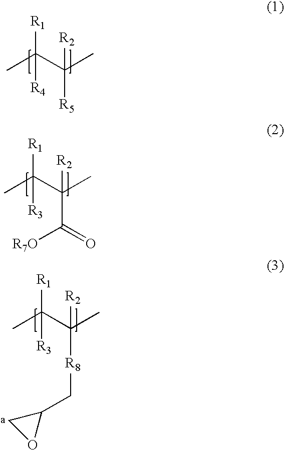

where each of R₁, R₂ and R₄ are individually selected from hydrogen, halogen, cyano, unsubstituted or substituted alkyl, or unsubstituted or substituted cycloalkyl, R₃ is selected from hydrogen, unsubstituted or substituted alkyl, or —C(═O)—O—R₆, R₅ is unsubstituted or substituted aryl, unsubstituted or substituted aralkyl, −C(═O)—O—R₆, —O—R₆, where R₆ is unsubstituted or substituted alkyl, unsubstituted or substituted cycloalkyl, unsubstituted or substituted aryl, or unsubstituted or substituted aralkyl, or R₄ and R₅ together with the carbon atoms to which they are attached form

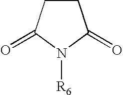

where R₆ is as defined above, R₇ is unsubstituted or substituted alkyl, unsubstituted or substituted cycloalkyl, unsubstituted or substituted aryl, unsubstituted or substituted aralkyl, -(unsubstituted or substituted alkylene)-O-(unsubstituted or substituted aryl), -(unsubstituted or substituted alkylene)-O-(unsubstituted or substituted alkyl), and R₈ is a linking group selected from —C(═O)—O—, —O—, —(CH₂)ₕ—O—, —O—(CH₂)ₕ—, —(CH₂)ₕ—, -(unsubstituted or substituted aryl)-O—, -(unsubstituted or substituted aryl)-, —O-(unsubstituted or substituted aryl)-, or R₈ and the carbon atom identified as ‘a’ together form a cycloaliphatic ring to which the cyclic ether is fused, and h is 1 to 5; optionally, an epoxy resin having a number average molecular weight Mₙ ranging from about 500 to about 12,000; and a thermal acid generator. In some instances, the polymer may not contain the repeating units of either formula (1) or formula (2). In other instances, the polymer may contain one or more repeating units of formula (1) and not formula (2); contain one or more repeating units of formula (2) and not formula (1); or contain one or more repeating units of formula (1) and one or more repeating units of formula (2). When the polymer contains repeating units of formulae (3) and (1), the repeating unit of formula (1) is present in an amount of from about 20 to about 80 mol %, further from about 40 to about 60 mol %, and the repeating unit of formula (3) is present in an amount of from about 20 to about 80 mol %, further from about 40 to about 60 mol %. When the polymer contains repeating units of formulae (3) and (2), the repeating unit of formula (2) is present in an amount of from about 20 to about 80 mol %, further from about 40 to about 60 mol %, and the repeating unit of formula (3) is present in an amount of from about 20 to about 80 mol %, further from about 40 to about 60 mol %. When the polymer contains repeating units of formulae (1), (2), and (3), the repeating unit of formula (1) is present in an amount of from about 10 to about 40 mol %, further from about 10 to about 30 mol %, the repeating unit of formula (2) is present in an amount of from about 10 to about 60 mol %, further from about 30 to about 60 mol %, and the repeating unit of formula (3) is present in an amount of from about 20 to about 80 mol %, further from about 30 to about 50 mol %.

In some instances, the gap fill material composition will contain a polymer having repeating units of formula (3) together with one or more repeating units of formula (1) and one or more repeating units of formula (2) together with an epoxy resin having a number average molecular weight Mₙ ranging from about 500 to about 12,000; and a thermal acid generator.

The present invention also relates to a polymer having repeating units of

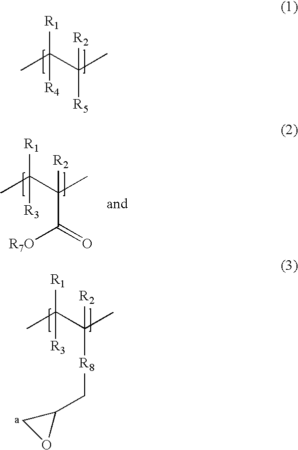

where each of R₁, R₂ and R₄ are individually selected from hydrogen, halogen, cyano, unsubstituted or substituted alkyl, or unsubstituted or substituted cycloalkyl, R₃ is selected from hydrogen, unsubstituted or substituted alkyl, or —C(═O)—O—R₆, R₅ is unsubstituted or substituted aryl, unsubstituted or substituted aralkyl, —C(═O)—O—R₆, —O—R₆, where R₆ is unsubstituted or substituted alkyl, unsubstituted or substituted cycloalkyl, unsubstituted or substituted aryl, or unsubstituted or substituted aralkyl, or R₄ and R₅ together with the carbon atoms to which they are attached form

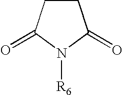

where R₆ is as defined above, R₇ is unsubstituted or substituted alkyl, unsubstituted or substituted cycloalkyl, unsubstituted or substituted aryl, unsubstituted or substituted aralkyl, -(unsubstituted or substituted alkylene)-O-(unsubstituted or substituted aryl), -(unsubstituted or substituted alkylene)-O-(unsubstituted or substituted alkyl), and R₈ is a linking group selected from —C(═O)—O—, —O—, —(CH₂)ₕ—O—, —O—(CH₂)ₕ—, —(CH₂)ₕ—, -(unsubstituted or substituted aryl)-O—, -(unsubstituted or substituted aryl)-, —O-(unsubstituted or substituted aryl)-, or R₈ and the carbon atom identified as ‘a’ together form a cycloaliphatic ring to which the cyclic ether is fused, h is 1 to 5, the repeating unit of formula (1) is present in an amount of from about 10 to about 40 mol %, further from about 10 to about 30 mol %, the repeating unit of formula (2) is present in an amount of from about 10 to about 60 mol %, further from about 30 to about 60 mol %, and the repeating unit of formula (3) is present in an amount of from about 20 to about 80 mol %, further from about 30 to about 50 mol %.

The present invention also relates to a process for manufacturing a semiconductor device comprising coating the gap fill material forming composition according to the present invention on a semiconductor substrate having a hole with aspect ratio shown in height/diameter of 1 or more and baking it. In addition, the present invention relates to a method for forming photoresist pattern for use in manufacture of semiconductor device, comprising coating the gap fill material forming composition according to the present invention on a semiconductor substrate having a hole with aspect ratio shown in height/diameter of 1 or more, baking it to form a gap fill material, forming a photoresist layer on the gap fill material, exposing the semiconductor substrate covered with the gap fill material and the photoresist layer to light, and developing the photoresist layer after the exposure to light.

### BRIEF DESCRIPTION OF THE DRAWINGS

FIG. 1 shows a typical Dual Damascene structure.

FIG. 2 shows a schematic of a Via-First Dual Damascene process.

FIG. 3 shows a schematic of a Trench-First Dual Damascene process.

FIG. 4 shows a schematic of a Via-First approach using a gap (also called via) filling material.

FIG. 5 shows a scanning electron microscope photograph of contact holes filled according to an example of the present invention.

### DETAILED DESCRIPTION OF THE INVENTION

The present invention relates to a novel gap fill material composition for via-filling comprising a polymer having at least one repeating unit of formula (3) and, optionally, one or more repeating units selected from formula (1), formula (2), and/or mixtures thereof

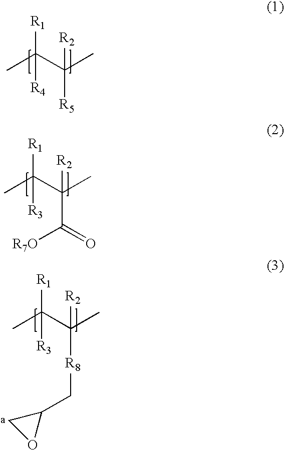

where each of R₁, R₂ and R₄ are individually selected from hydrogen, halogen, cyano, unsubstituted or substituted alkyl, or unsubstituted or substituted cycloalkyl, R₃ is selected from hydrogen, unsubstituted or substituted alkyl, or —C(═O)—O—R₆, R₅ is unsubstituted or substituted aryl, unsubstituted or substituted aralkyl, —C(═O)—O—R₆, —O—R₆, where R₆ is unsubstituted or substituted alkyl, unsubstituted or substituted cycloalkyl, unsubstituted or substituted aryl, or unsubstituted or substituted aralkyl, or R₄ and R₅ together with the carbon atoms to which they are attached form

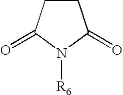

where R₆ is as defined above, R₇ is unsubstituted or substituted alkyl, unsubstituted or substituted cycloalkyl, unsubstituted or substituted aryl, unsubstituted or substituted aralkyl, -(unsubstituted or substituted alkylene)-O-(unsubstituted or substituted aryl), -(unsubstituted or substituted alkylene)-O-(unsubstituted or substituted alkyl), and R₈ is a linking group selected from —C(═O)—O—, —O—, —(CH₂)ₕ—O—, —O—(CH₂)ₕ—, —(CH₂)ₕ—, -(unsubstituted or substituted aryl)-O—, -(unsubstituted or substituted aryl)-, —O-(unsubstituted or substituted aryl)-, or R₈ and the carbon atom identified as ‘a’ together form a cycloaliphatic ring to which the cyclic ether is fused, and h is 1 to 5; optionally, an epoxy resin having a number average molecular weight Mₙ ranging from about 500 to about 12,000; and a thermal acid generator. In some instances, the polymer may not contain the repeating units of either formula (1) or formula (2). In other instances, the polymer may contain one or more repeating units of formula (1) and not formula (2); contain one or more repeating units of formula (2) and not formula (1); or contain one or more repeating units of formula (1) and formula (2). When the polymer contains repeating units of formulae (3) and (1), the repeating unit of formula (1) is present in an amount of from about 20 to about 80 mol %, further from about 40 to about 60 mol %, and the repeating unit of formula (3) is present in an amount of from about 20 to about 80 mol %, further from about 40 to about 60 mol %. When the polymer contains repeating units of formulae (3) and (2), the repeating unit of formula (2) is present in an amount of from about 20 to about 80 mol %, further from about 40 to about 60 mol %, and the repeating unit of formula (3) is present in an amount of from about 20 to about 80 mol %, further from about 40 to about 60 mol %. When the polymer contains repeating units of formulae (1), (2), and (3), the repeating unit of formula (1) is present in an amount of from about 10 to about 40 mol %, further from about 10 to about 30 mol %, the repeating unit of formula (2) is present in an amount of from about 10 to about 60 mol %, further from about 30 to about 60 mol %, and the repeating unit of formula (3) is present in an amount of from about 20 to about 80 mol %, further from about 30 to about 50 mol %.

In some instances, the gap fill material composition will contain a polymer having repeating units of formula (3) together with one or more repeating units of formula (1) and one or more repeating units of formula (2) together with an epoxy resin having a number average molecular weight Mₙ ranging from about 500 to about 12,000; and a thermal acid generator.

The present invention also relates to a polymer having repeating units of

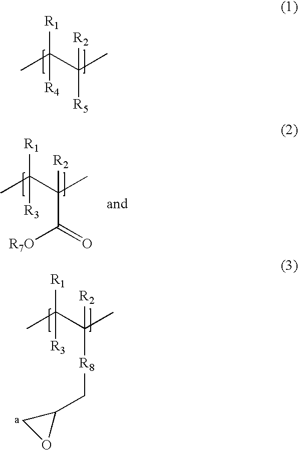

where each of R₁, R₂ and R₄ are individually selected from hydrogen, halogen, cyano, unsubstituted or substituted alkyl, or unsubstituted or substituted cycloalkyl, R₃ is selected from hydrogen, unsubstituted or substituted alkyl, or —C(═O)—O—R₆, R₅ is unsubstituted or substituted aryl, unsubstituted or substituted aralkyl, —C(═O)—O—R₆, —O—R₆, where R₆ is unsubstituted or substituted alkyl, unsubstituted or substituted cycloalkyl, unsubstituted or substituted aryl, or unsubstituted or substituted aralkyl, or R₄ and R₅ together with the carbon atoms to which they are attached form

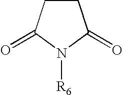

where R₆ is as defined above, R₇ is unsubstituted or substituted alkyl, unsubstituted or substituted cycloalkyl, unsubstituted or substituted aryl, unsubstituted or substituted aralkyl, -(unsubstituted or substituted alkylene)-O-(unsubstituted or substituted aryl), -(unsubstituted or substituted alkylene)-O-(unsubstituted or substituted alkyl), and R₈ is a linking group selected from —C(═O)—O—, —O—, —(CH₂)ₕ—O—, —O—(CH₂)ₕ—, —(CH₂)ₕ—, -(unsubstituted or substituted aryl)-O—, -(unsubstituted or substituted aryl)-, —O-(unsubstituted or substituted aryl)-, or R₈ and the carbon atom identified as ‘a’ together form a cycloaliphatic ring to which the cyclic ether is fused, h is 1 to 5, the repeating unit of formula (1) is present in an amount of from about 10 to about 40 mol %, further from about 10 to about 30 mol %, the repeating unit of formula (2) is present in an amount of from about 10 to about 60 mol %, further from about 30 to about 60 mol %, and the repeating unit of formula (3) is present in an amount of from about 20 to about 80 mol %, further from about 30 to about 50 mol %.

The present invention also relates to a process for manufacturing a semiconductor device comprising coating the gap fill material forming composition according to the present invention on a semiconductor substrate having a hole with aspect ratio shown in height/diameter of 1 or more and baking it. In addition, the present invention relates to a method for forming photoresist pattern for use in manufacture of semiconductor device, comprising coating the gap fill material forming composition according to the present invention on a semiconductor substrate having a hole with aspect ratio shown in height/diameter of 1 or more, baking it to form a gap fill material, forming a photoresist layer on the gap fill material, exposing the semiconductor substrate covered with the gap fill material and the photoresist layer to light, and developing the photoresist layer after the exposure to light.

As mentioned above, the gap fill material composition for via-filling comprises a polymer having at least one repeating unit of formula (3) and optionally one or more repeating units selected from formula (1), formula (2), and/or mixtures thereof. In some instances, the polymer may not contain the repeating units of either formula (1) or formula (2). In other instances, the polymer may contain one or more repeating units of formula (1) and not formula (2); contain one or more repeating units of formula (2) and not formula (1); or contain one or more repeating units of formula (1) and one or more repeating units of formula (2). When the polymer contains repeating units of formulae (3) and (1), the repeating unit of formula (1) is present in an amount of from about 20 to about 80 mol %, further from about 40 to about 60 mol %, and the repeating unit of formula (3) is present in an amount of from about 20 to about 80 mol %, further from about 40 to about 60 mol %. When the polymer contains repeating units of formulae (3) and (2), the repeating unit of formula (2) is present in an amount of from about 20 to about 80 mol %, further from about 40 to about 60 mol %, and the repeating unit of formula (3) is present in an amount of from about 20 to about 80 mol %, further from about 40 to about 60 mol %. When the polymer contains repeating units of formulae (1), (2), and (3), the repeating unit of formula (1) is present in an amount of from about 10 to about 40 mol %, further from about 10 to about 30 mol %, the repeating unit of formula (2) is present in an amount of from about 10 to about 60 mol %, further from about 30 to about 60 mol %, and the repeating unit of formula (3) is present in an amount of from about 20 to about 80 mol %, further from about 30 to about 50 mol %. The gap fill material compositions containing the aforementioned polymers have good via fill/low void forming properties when baked at temperatures up to about 250° C. For those instances when the gap fill material compositions are rebaked during secondary processing at temperatures of 300° C. and greater, polymer will preferably contain repeating units of formulae (1), (2), and (3).

Alkyl refers to both straight and branched chain saturated hydrocarbon groups having 1 to 20 carbon atoms, for example, methyl, ethyl, propyl, isopropyl, tertiary butyl, dodecyl, and the like.

Examples of the linear or branched alkylene group can have from 1 to 20 carbon atoms and include such as, for example, methylene, ethylene, propylene and octylene groups.

Aryl refers to an unsaturated aromatic carbocyclic group of from 6 to 20 carbon atoms having a single ring or multiple condensed (fused) rings and include, but are not limited to, for example, phenyl, tolyl, dimethylphenyl, 2,4,6-trimethylphenyl, naphthyl, anthryl and 9,10-dimethoxyanthryl groups.

Aralkyl refers to an alkyl group containing an aryl group. It is a hydrocarbon group having both aromatic and aliphatic structures, that is, a hydrocarbon group in which an alkyl hydrogen atom is substituted by an aryl group, for example, tolyl, benzyl, phenethyl and naphthylmethyl groups.

Cycloalkyl refers to cyclic alkyl groups of from 3 to 50 carbon atoms having a single cyclic ring or multiple condensed (fused) rings. Examples include cyclopropyl group, cyclopentyl group, cyclohexyl group, cycloheptyl group, cyclooctyl, adamantyl, norbornyl, isoboronyl, camphornyl, dicyclopentyl, .alpha.-pinel, tricyclodecanyl, tetracyclododecyl and androstanyl groups. In these monocyclic or polycyclic cycloalkyl groups, the carbon atom may be substituted by a heteroatom such as oxygen atom.

Furthermore, and as used herein, the term “substituted” is contemplated to include all permissible substituents of organic compounds. In a broad aspect, the permissible substituents include acyclic and cyclic, branched and unbranched, carbocyclic and heterocyclic, aromatic and non-aromatic substituents of organic compounds. Illustrative substituents include, for example, those described hereinabove. The permissible substituents can be one or more and the same or different for appropriate organic compounds. For purposes of this invention, the heteroatoms such as nitrogen may have hydrogen substituents and/or any permissible substituents of organic compounds described herein which satisfy the valences of the heteroatoms. This invention is not intended to be limited in any manner by the permissible substituents of organic compounds.

For formula (1), repeating units can be derived from monomers such as styrene, hydroxystyrene, acetoxystyrene, 1-methyl-styrene, N-phenyl maleimide, N-benzyl maleimide, phenyl vinyl ether, vinyl benzoate, vinyl 4-tert-butylbenzoate, and mixtures thereof, and the like, and vinyl ethers, for example, methyl vinyl ether, ethyl vinyl ether, n-propyl vinyl ether, isopropyl vinyl ether, n-butyl vinyl ether, sec-butyl vinyl ether, t-butyl vinyl ether, n-pentyl vinyl ether, t-pentyl vinyl ether, iso-pentyl vinyl ether, sec-pentyl vinyl ether, neopentyl vinyl ether, ethylene glycol vinyl ether, ethylene glycol butyl vinyl ether, octyl vinyl ether, isooctyl vinyl ether, 2-ethylehexyl vinyl ether, 1,4-butanediol vinyl ether, cyclohexyl vinyl ether, 4-hydroxybutyl vinyl ether, isobutyl vinyl ether, and mixtures thereof, and the like.

For formula (2), repeating units can be derived from monomers such as acrylates, for example, methyl acrylate, ethyl acrylate, propyl acrylate, isopropyl acrylate, butyl acrylate, isobutyl acrylate, sec-butyl acrylate, t-butyl acrylate, 2-phenyl-2-hydroxyethyl acrylate, benzyl acrylate, ethylene glycol phenyl ether acrylate, hydroxyphenyl acrylate, phenoxypropyl acrylate, 2-hydroxy-3-phenoxypropyl acrylate, phenyl acrylate, benzyl acrylate, and mixtures thereof, and the like, methacrylates, for example, methyl methacrylate, ethyl methacrylate, propyl methacrylate, 2-hydroxypropyl methacrylate, 2-ethylhexyl methacrylate, isopropyl methacrylate, butyl methacrylate, isobutyl methacrylate, sec-butyl methacrylate, t-butyl methacrylate, phenyl-2-hydroxyethyl methacrylate, benzyl methacrylate, ethylene glycol phenyl ether methacrylate, phenoxypropyl methacrylate, 2-hydroxy-3-phenoxypropyl methacrylate, phenyl methacrylate, hydroxyphenyl methacrylate, benzyl methacrylate, and mixtures thereof, and the like, maleates, for example, dimethyl maleate, diethyl maleate, and mixtures thereof, and the like, as well as mixtures of acrylates, methacrylates, maleates, and vinyl ethers. In some instance, the recurring units are selected from methyl acrylate, ethyl acrylate, propyl acrylate, isopropyl acrylate, butyl acrylate, isobutyl acrylate, sec-butyl acrylate, t-butyl acrylate, and mixtures thereof.

For formula (3), repeating units can be derived from monomers such as glycidyl acrylate, glycidyl methacrylate, glycidyl vinyl ether, glycidyl allyl ether, p-glycidyloxystyrene, 4-vinyl-1-cyclohexene-1,2-epoxide, glycidyl vinyl benzene ether, glycidyloxystyrene, glycidyl butyl acrylate, glycidyl butyl methacrylate, and mixtures thereof, and the like.

In some instances, the repeating units of formula (1) and formula (2) are selected from styrene, hydroxystyrene, acetoxystyrene, 1-methyl-styrene, 2-phenyl-2-hydroxyethyl acrylate, benzyl acrylate, ethylene glycol phenyl ether acrylate, phenoxypropyl acrylate, 2-hydroxy-3-phenoxypropyl acrylate, hydroxyphenyl acrylate, phenyl acrylate, benzyl acrylate, and mixtures thereof.

When the polymer contains repeating units of formulae (3) and (1), the repeating unit of formula (1) is present in an amount of from about 20 to about 80 mol %, further from about 40 to about 60 mol %, and the repeating unit of formula (3) is present in an amount of from about 20 to about 80 mol %, further from about 40 to about 60 mol %. When the polymer contains repeating units of formulae (3) and (2), the repeating unit of formula (2) is present in an amount of from about 20 to about 80 mol %, further from about 40 to about 60 mol %, and the repeating unit of formula (3) is present in an amount of from about 20 to about 80 mol %, further from about 40 to about 60 mol %. When the polymer contains repeating units of formulae (1), (2), and (3), the repeating unit of formula (1) is present in an amount of from about 10 to about 40 mol %, further from about 10 to about 30 mol %, the repeating unit of formula (2) is present in an amount of from about 10 to about 60 mol %, further from about 30 to about 60 mol %, and the repeating unit of formula (3) is present in an amount of from about 20 to about 80 mol %, further from about 30 to about 50 mol %.

The polymer used herein can be made using free radical polymerization techniques known to those having ordinary skill in the art.

An optional component of the composition of the invention is an epoxy resin. Examples of epoxy resins include polyglycidyl ethers of polyhydric phenols, epoxy novolacs or similar glycidated polyphenolic resins, polyglycidyl ethers of glycols or polyglycols, and polyglycidyl esters of polycarboxylic acids. Further examples of epoxy resins include bisphenol A epoxy resins, tetramethyl bisphenol A epoxy resins, bisphenol F epoxy resins, bisphenol S epoxy resins, 2,2-bis(4-hydroxy-3-methylphenyl)propane epoxy resins, bisphenol M epoxy resins, bisphenol P epoxy resins, bisphenol Z epoxy resins, bisphenol AP epoxy resins, bisphenol E epoxy resins, phenol novolac type epoxy resins, o-cresol novolac type epoxy resins, phthalic acid diglycidyl ester, tetrahydrophthalic acid diglycidyl ester, hexahydrophthalic acid diglycidyl ester, p-hydroxybenzoic acid diglycidyl ester, and the like. When used, these epoxy resins may be used alone or in admixture. The epoxy resin can be saturated or unsaturated, linear or branched, aliphatic, cycloaliphatic, aromatic or heterocyclic, and may bear substituents which do not materially/chemically interfere with the curing reaction. The epoxy resin may be monomeric or polymeric, liquid or solid, but is preferably liquid at room temperature. Suitable epoxy resins include glycidyl ethers prepared by reacting epichlorohydrin with a compound containing two hydroxyl groups carried out under alkaline reaction conditions.

Polyglycidyl ethers of polyhydric phenols can be produced, for example, by reacting an epihalohydrin with a polyhydric phenol in the presence of an alkali. Examples of suitable polyhydric phenols include: (2,2-bis(4-hydroxyphenyl)propane) bisphenol-A; tetramethyl bisphenol A (4,4′-isopropylidenebis(2,6-dimethylphenol)), bisphenol F (bis(4-hydroxyphenyl)methane), bisphenol S (4,4′-sulfonyldephenol), bisphenol M (4,4′-(1,3-phenylenediisopropylidene)bisphenol), bisphenol P (4,4′-(1,4 phenylenediisopropylidene)bisphenol), bisphenol Z (4,4′-cyclohexylidenebisphenol), bisphenol AP (4,4′-(1-phenylethylidene)bisphenol), bisphenol E (4,4′-ethylidenebisphenol), 2,2-bis(4-hydroxy-3-tert-butylphenyl)propane; 2,2-bis(4-hydroxy-3-methylphenyl)propane, 1,1-bis(4-hydroxyphenyl)ethane; 1,1-bis(4-hydroxyphenyl)isobutane; bis(2-hydroxy-1-naphthyl)methane; 1,5-dihydroxynaphthalene; 1,1-bis(4-hydroxy-3-alkylphenyl)ethane, 2,2-bis(3-sec-butyl-4-hydroxyphenyl)propane, 2,2-bis(4-hydroxy-3-isopropylphenyl)propane, 2,2-bis(4-hydroxyphenyl)butane, α,α′-bis(4-hydroxy-3,5-dimethylphenyl)-1,4-diisopropylbenzene, and the like. Suitable polyhydric phenols can also be obtained from the reaction of phenol with aldehydes such as formaldehyde (bisphenol-F) or non symmetrical ketones. Fusion products of these polyglycidyl ethers of polyhydric phenols with phenolic compounds such as bisphenol-A are also suitable as epoxy resins, such as those described in U.S. Pat. Nos. 3,477,990 and 4,734,468.

The glycidyl ether epoxides resins are generally prepared by the reaction of one mole of a bisphenol type, or other dihydroxyl compound, compound and two moles of epichlorohydrin. In some instances, the bisphenol compounds can be blended, for example bisphenol A and bisphenol F. A blend of Bisphenol F type resin and Bisphenol A type resin, commercially available from Vantico as ARALDITE PY720. Other suitable Bisphenol A/F blends commercially available include EPIKOTE 235, 234 and 238 (Shell), NPEF 185, 198 and 187 (Whyte Chemicals), DER 351, 356 and 352 (Dow), or RUTAPOX 0169 or 0166 (Bakelite). Bisphenol F type resin is available from CVC Specialty Chemicals under the designation 8230E, EPIKOTE 862 (Resolution), or Whyte Chemicals as NPEF 170. Bisphenol-A type resin is commercially available from Resolution Technology as EPON 828, 828EL or 828XA. Another type of epoxy resin is epoxy novolac resin. Epoxy novolac resin is commonly prepared by the reaction of phenolic resin and epichlorohydrin. One example of an epoxy novolac resin is poly(phenyl glycidyl ether)-co-formaldehyde. Examples of the foregoing include

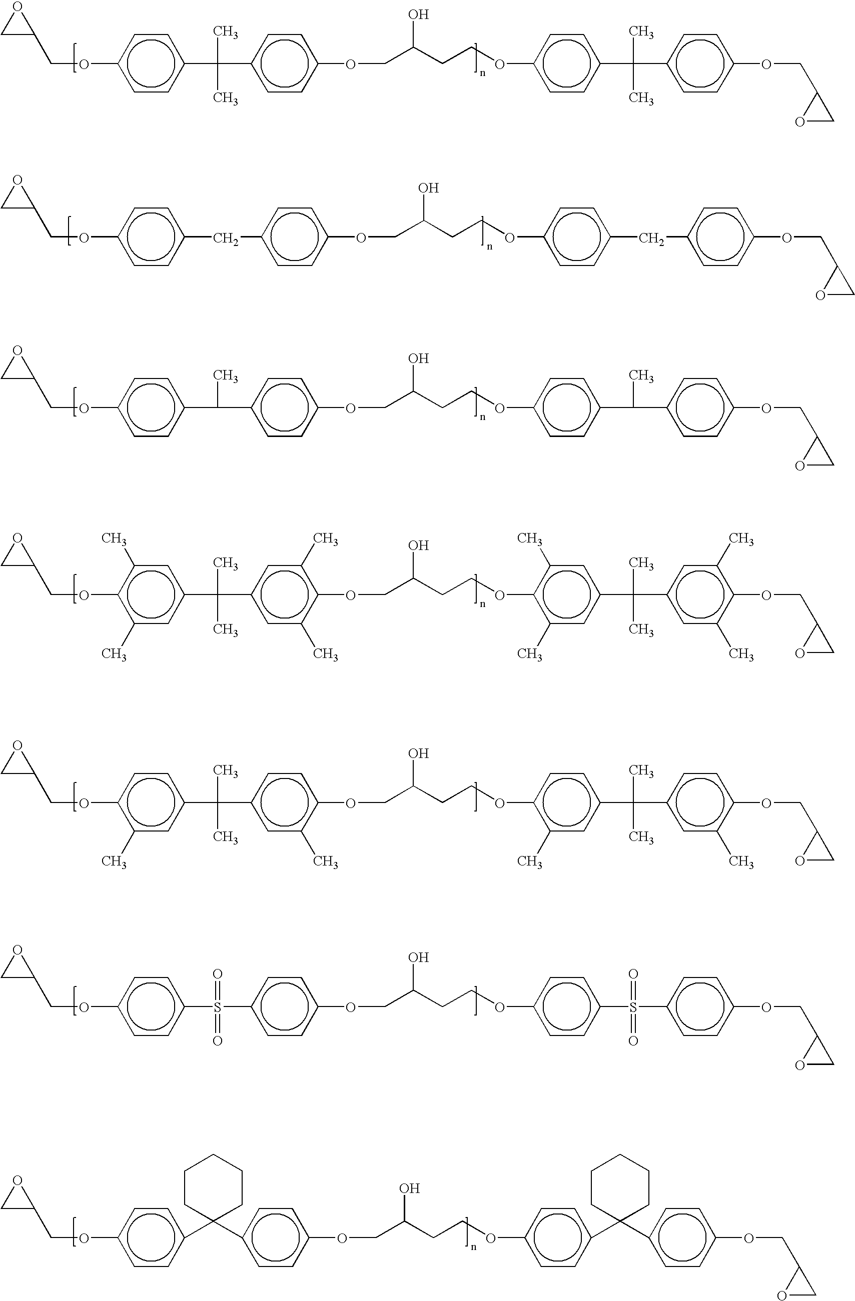

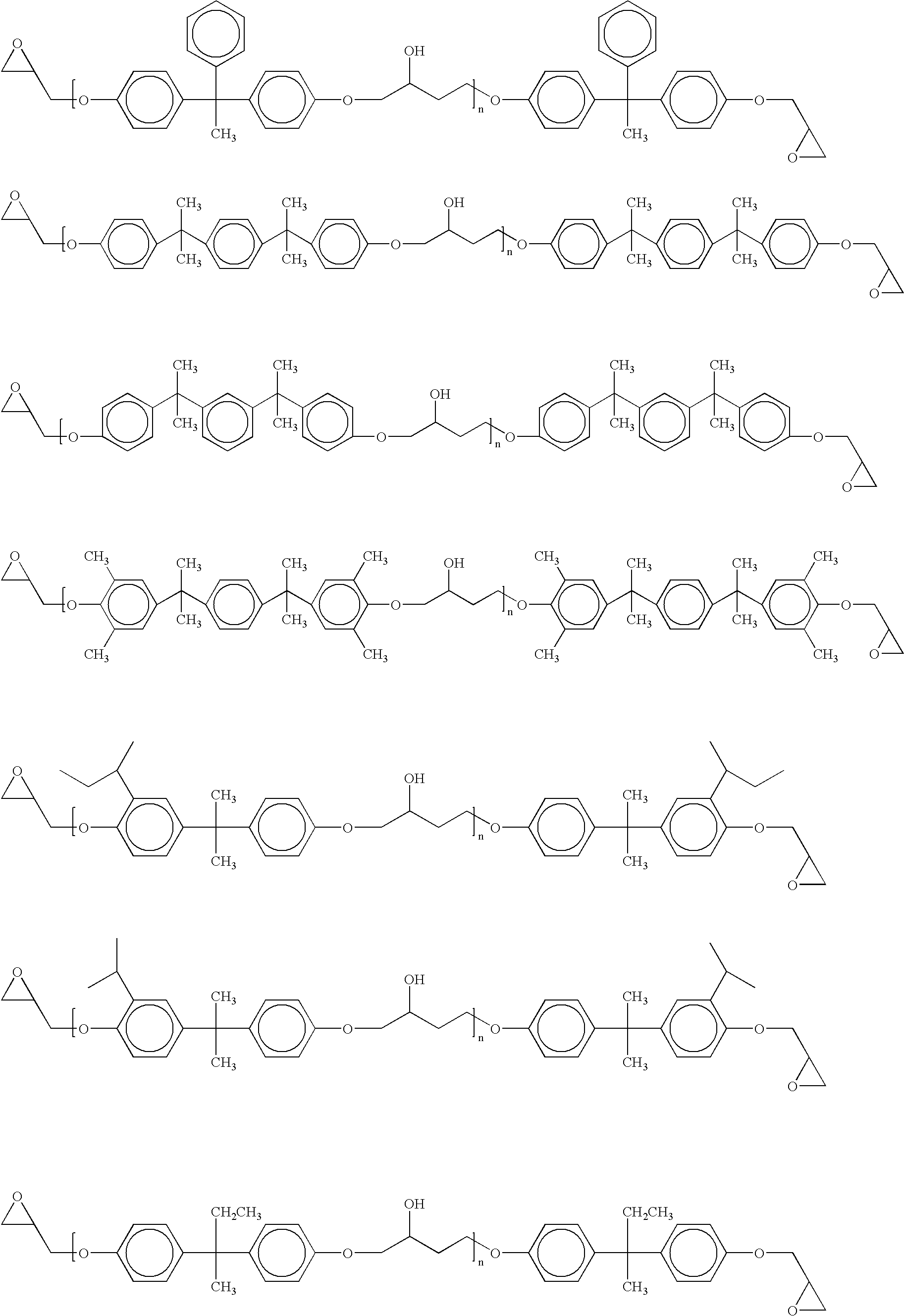

where n is about 2 to about 45.

The molecular weight of the epoxy resin can range from about 500 to about 12,000. The epoxy resin, when present in the composition, ranges from about 0.1 to about 30 wt %.

Another component in the composition of the present invention is a thermal acid generator. The thermal acid generator is generally activated at 90° C. and more preferably at above 120° C., and even more preferably at above 150° C. Examples of thermal acid generators are butane sulfonic acid, triflic acid, nanoflurobutane sulfonic acid, nitrobenzyl tosylates, such as 2-nitrobenzyl tosylate, 2,4-dinitrobenzyl tosylate, 2,6-dinitrobenzyl tosylate, 4-nitrobenzyl tosylate; benzenesulfonates such as 2-trifluoromethyl-6-nitrobenzyl 4-chlorobenzenesulfonate, 2-trifluoromethyl-6-nitrobenzyl 4-nitro benzenesulfonate; phenolic sulfonate esters such as phenyl, 4-methoxybenzenesulfonate; alkyl ammonium salts of organic acids, such as triethylammonium salt of 10-camphorsulfonic acid, and the like, and mixtures thereof.

Examples of solvents for the coating composition include alcohols, esters, glymes, ethers, glycol ethers, glycol ether esters, ketones, cyclic ketones, and mixtures thereof. Examples of such solvents include, but are not limited to, propylene glycol methyl ether, propylene glycol methyl ether acetate, cyclopentanone, cyclohexanone, 2-heptanone, ethyl 3-ethoxy-propionate, propylene glycol methyl ether acetate, ethyl lactate, and methyl 3-methoxypropionate, and the like, etc. The solvent is typically present in an amount of from about 10 to about 95 weight percent.

Since the composition is coated on top of the substrate and is further subjected to additional processing, it is envisioned that the composition is of sufficiently low metal ion level and purity that the properties of the semiconductor device are not adversely affected. Treatments known in the art can be used to reduce the concentration of metal ions and to reduce particles.

The gap fill material forming composition according to the present invention may contain further rheology controlling agents, adhesion auxiliaries, surfactants, etc., if necessary.

The rheology controlling agents are added mainly aiming at increasing the flowability of the gap fill material forming composition and in particular in the baking step, increasing fill property of the gap fill material forming composition into the inside of holes.

The adhesion auxiliaries are added mainly for the purpose of increasing the adhesion between a substrate, or an anti-reflective coating or a photoresist and a gap fill material formed from a gap fill material forming composition.

The gap fill material forming composition according to the present invention may contain surfactants with view to preventing the occurrence of pinholes or striations and further increasing coatability not to cause surface unevenness.

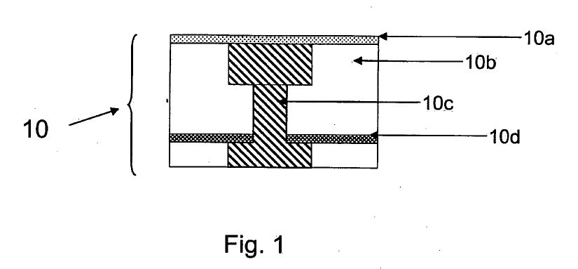

Dual Damascene (DD) is a process employed in Integrated Circuit (IC) fabrication for forming interconnect structures of copper metal lines and columnar metal via connecting the lines in adjacent layers as shown in FIG. 1. As shown in FIG. 1, substrate 10 has a cap layer 10a and an etch stop 10d, between which is a low k material 10b surrounding the copper metal line 10c. DD is also commonly referred as the name of structure generated by the DD process.

As discussed above, there are two types of widely used DD processes in the art. One is the so-called Via-First approach and the other the Trench-First approach.

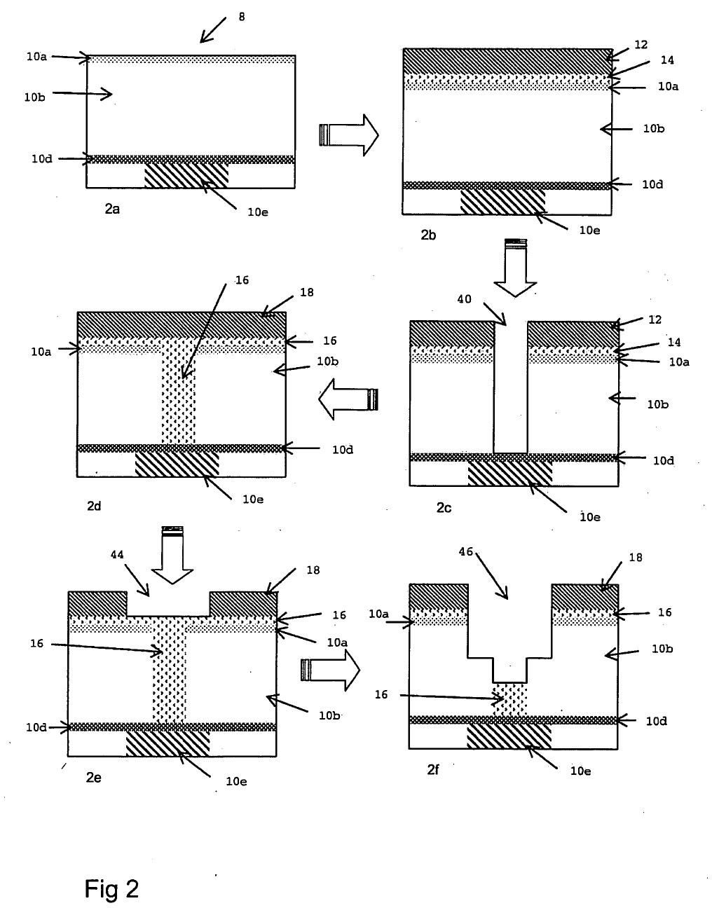

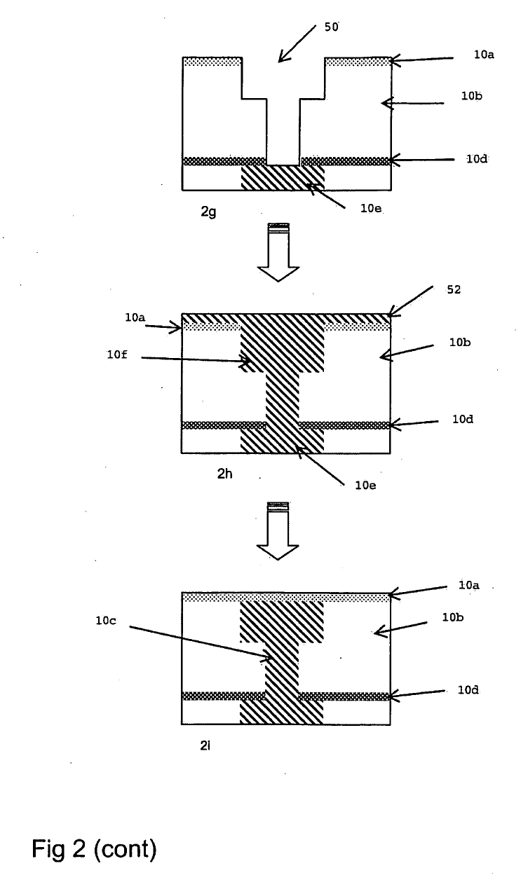

FIG. 2 illustrates a schematic flow of a typical Via-First DD process. In the Via-First approach, the substrate 8, which has a cap layer 10a and an etch stop 10d, between which is a low k material 10b (and which is also found below etch stop 10d), and a copper line 10e (shown in FIG. 2a), is spin-coated with a bottom antireflective coating 14 (BARC) and photoresist 12 (shown in FIG. 2b). Lithographic processes then generate a via pattern in the photoresist film. A plasma etch step using the resist pattern as a mask cuts through the photoresist 12, BARC 14, cap layer 10a, and low k material 10b (inter layer dielectric, ILD) down to etch stop 10d to form via 40 in the ILD (shown in FIG. 2c). Photoresist 12 and BARC 14 are then stripped. A second BARC coating 16 and a second photoresist 18 are then coated onto the substrate. The second BARC coating 16 will not only form a thin film on surface of the cap layer 10a of the substrate but also fully fill the preformed via 40 in the ILD (shown in FIG. 2d). A photoresist trench pattern 44 is then generated (shown in FIG. 2e) by another photolithographic step and similarly transferred into the ILD by a plasma etching process to form trench 46 (shown in FIG. 2f). During the second etch process, BARC material 16 should not be completely removed from via 40. The BARC material 48 on the bottom of via 40 prevents the etch stop 10d layer from being broken through to expose the underlying copper line 10e to reactive etch plasma. The photoresist 18 and BARC 16 from the other photolithographic step are then stripped either through dry (plasma) or wet etch chemistry. A special soft low energy plasma etch is applied to remove BARC material 48 and open the etch stop 10d to copper line 10e, forming trench 50 (shown in FIG. 2g). Bulk copper 10f is deposited into the structure, filling trench 50, using an electroplating process (shown in FIG. 2h). Excess copper 52 on the surface of cap layer 10a on the substrate is removed by a chemical mechanical planarization (CMP) process. A chemical vapor deposition (CVD) process deposits a thin cap layer on the substrate surface to cover the deposited copper and finishes the DD process (shown in FIG. 2i).

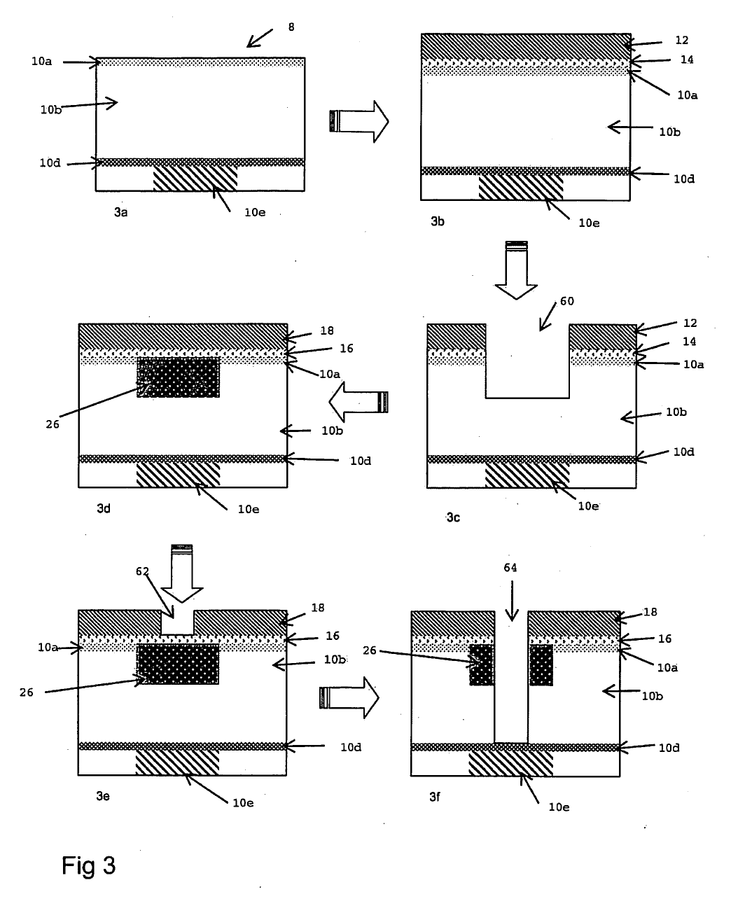

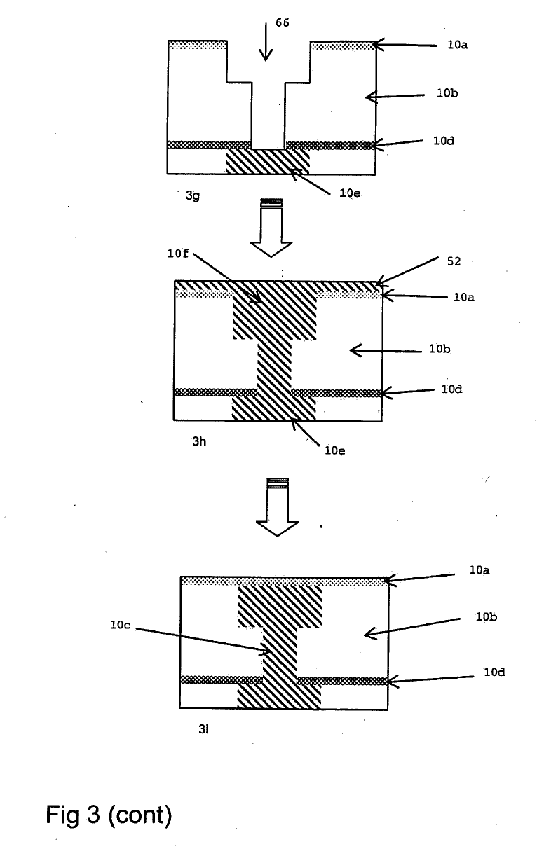

FIG. 3 shows a schematic flow of a typical Trench-First process. In the Trench-First approach, most of the process is similar to the aforementioned Via-First approach except that the formation sequence of the two lithographic patterns are reversed. As shown in FIG. 3, in a Trench-First approach, the trench pattern is formed after the first lithographic process instead a via pattern. The trench is transferred into the ILD by a plasma etch step only to a desired depth (shown in FIGS. 3a to 3c). Thus, the substrate 8, which has a cap layer 10a and an etch stop 10d, between which is a low k material 10b (and which is also found below etch stop 10d), and a copper line 10e (shown in FIG. 3a), is spin-coated with a bottom antireflective coating 14 (BARC) and photoresist 12 (shown in FIG. 3b). Lithographic processes then generate a trench pattern in the photoresist film. A plasma etch step using the resist pattern as a mask cuts through the photoresist 12, BARC 14, cap layer 10a, and partially through low k material 10b (inter layer dielectric, ILD) to form trench 60 in the ILD (shown in FIG. 3c). Photoresist 12 and BARC 14 materials are stripped, which is followed by a second lithographic process for generating a via pattern in which a second BARC 16, which not only forms a thin film on the surface of cap layer 10a of the substrate but also fills trench 60 (BARC 26), with photoresist 18 coated over BARC 16 (shown in FIG. 3d). A photoresist trench pattern 62 is then generated (shown in FIG. 3e) by another photolithographic step and similarly transferred into the ILD by a plasma etching process to form via 64 (shown in FIG. 3f) and then to form trench pattern 66. During via 64 formation, a special soft low energy plasma etch is applied to remove low k material 10c to etch stop 10d. This is then continued to cut through etch stop 10c to open it up to copper line 10e when forming trench structure 66 (shown in FIG. 3g). Bulk copper 10f is deposited into the structure, filling trench 66, using an electroplating process (shown in FIG. 3h). Excess copper 52 on the surface of cap layer 10a on the substrate is removed by a chemical mechanical planarization (CMP) process. A chemical vapor deposition (CVD) process deposits a thin cap layer on the substrate surface to cover the deposited copper and finishes the DD process (shown in FIG. 3i).

For manufacturing large node such as 90 nm of IC devices, a BARC material can function well in both filling via/trench patterns in ILD and suppressing reflectivity for the lithographic processes. However, due to continual scaling of feature size in advanced IC devices, performances of via/trench filling and reflectivity control may need to be carried out by two different materials. Special polymer design and judicious formulation optimization are necessary for via/trench filling material development. In advanced DD processes, preparation for a second lithographic process involves in via (Via-First) or trench (Trench-First) pattern filling using a fill material before BARC and photoresist coating. In general, the via or trench is overfilled to make sure all patterns in the substrate are covered. Excess fill material on top of the substrate is removed through either plasma etching or a CMP step.

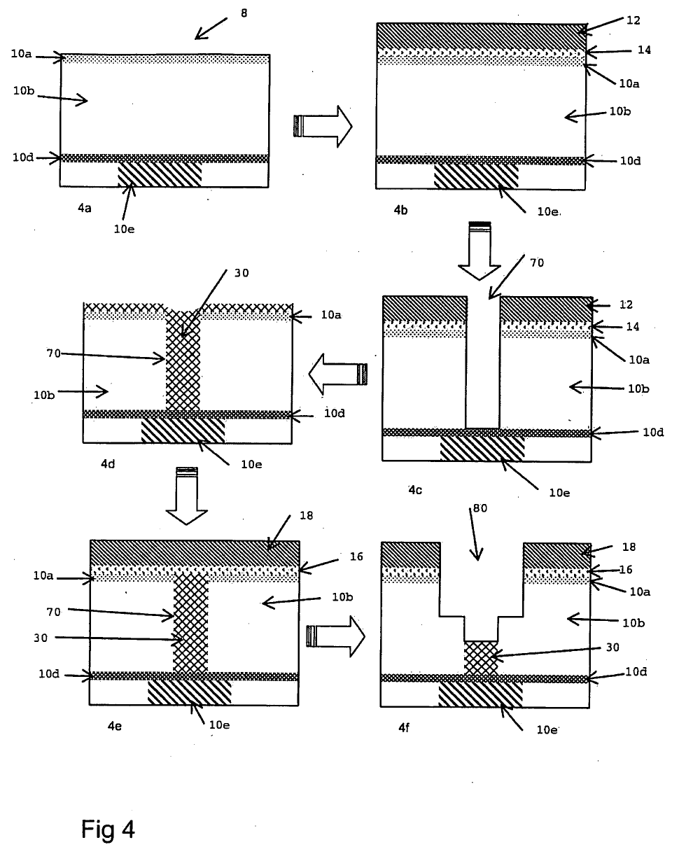

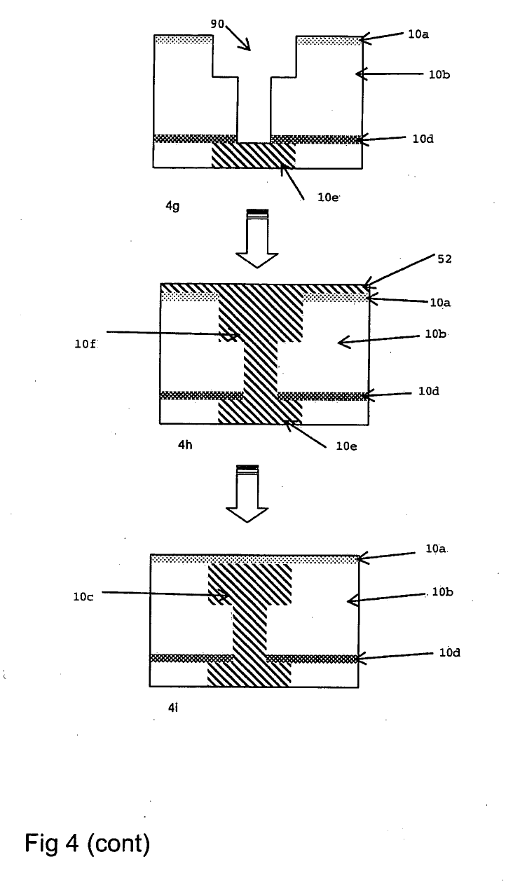

FIG. 4 presents a process flow of a Via-First DD approach involving in application of a filling material. In the Via-First approach involving in application of a filling material, the substrate 8, which has a cap layer 10a and an etch stop 10d, between which is a low k material 10b (and which is also found below etch stop 10d), and a copper line 10e (shown in FIG. 4a), is spin-coated with a bottom antireflective coating 14 (BARC) and photoresist 12 (shown in FIG. 4b). Lithographic processes then generate a via pattern in the photoresist film. A plasma etch step using the resist pattern as a mask cuts through the photoresist 12, BARC 14, cap layer 10a, and low k material 10b (inter layer dielectric, ILD) down to etch stop 10d to form via 70 in the ILD (shown in FIG. 4c). Photoresist 12 and BARC 14 are then stripped. Fill material 30 is then coated over via 70 and cap layer 10a. Depending upon the thickness of fill material 30 on cap layer 10a, there may be a small dimple formed (shown in FIG. 4d). The excess of fill material 70 on cap layer 10a is stripped off and a second BARC coating 16 and a second photoresist 18 are then coated onto the substrate (shown in FIG. 4e). A photoresist trench pattern 80 is then generated by another photolithographic step and similarly transferred into the ILD by a plasma etching process to form trench 80 (shown in FIG. 4f). During the second etch process, fill material 30 should not be completely removed from via 70. The fill material 30 on the bottom of via 70 prevents the etch stop 10d layer from being broken through to expose the underlying copper line 10e to reactive etch plasma. The photoresist 18 and BARC 16 from the other photolithographic step are then stripped either through dry (plasma) or wet etch chemistry. A special soft low energy plasma etch is applied to remove fill material 30 and open the etch stop 10d to copper line 10e, forming trench 90 (shown in FIG. 4g). Bulk copper 10f is deposited into the structure, filling trench 90, using an electroplating process (shown in FIG. 4h). Excess copper 52 on the surface of cap layer 10a on the substrate is removed by a chemical mechanical planarization (CMP) process. A chemical vapor deposition (CVD) process deposits a thin cap layer on the substrate surface to cover the deposited copper and finishes the DD process (shown in FIG. 4i).

The gap fill material forming material forming composition of the present invention is used in a manufacture process of semiconductor devices by using substrate having holes with an aspect ratio shown in height/diameter of 1 or more, particularly in a lithography process of dual damascene process.

In dual damascene process, interconnect trench (trench) and connection hole (via hole) are provided at the same part of a substrate, and copper is utilized as interconnect material for bedding. The substrate used in dual damascene process has holes with an aspect ratio shown in height/diameter of 1 or more, generally 1 to 20. Therefore, it is difficult to fill the holes having the above-mentioned aspect ratio to the narrow parts thereof with any conventional sub-layer material such as anti-reflective coating material or the like, and as the result of it, there was a problem that voids (gaps) are formed in the inside of the holes. In addition, when the conventional sub-layer material is applied on a substrate having holes with a spinner, and then baked, dimples of the sub-layer material are formed at the upper part of the holes, and this causes insufficient flattening property. Consequently, even when a photoresist is applied thereon, an excellent pattern is not obtained due to diffused reflection resulting from unevenness from the lower surface of the photoresist.

On the other hand, by using the gap fill material forming composition of the present invention, a high fill property and flattening property of the gap fill material formed therefrom can be accomplished.

Hereinafter, the utilization of the gap fill material forming composition of the present invention is described.

### EXAMPLES

### Synthetic Example 1

224.26 g of propylene glycol monomethyl ether acetate, 10.4 g (0.10 mol) of styrene, 17.2 g (0.20 mol) of methyl acrylate and 28.43 g (0.20 mol) of glycidyl methacrylate were charged into a suitably sized flask having a thermometer, a cold water condenser, a mechanical stirrer, an external heating source, and nitrogen source. The materials were stirred under nitrogen atmosphere until dissolved (about 30 minutes) at room temperature (˜25° C.). Then, the temperature of the flask contents was raised to 75° C. While maintaining the temperature at 75° C., 1.56 g (9.5×10⁻³ mol) of azobisisobutyronitrile was introduced into the flask. After stirring under nitrogen atmosphere at 75° C. for 20 hours, the temperature was raised to 100° C. After maintaining this temperature for 1 hour, the reaction solution was cooled down to room temperature and the reaction mixture was poured into DI water, yielding, by precipitation, a white polymer solid. The white polymer solid was washed and dried under vacuum at 50° C., yielding 57.9 g (>99%). GPC analysis of the resulting polymer showed that it had a number average molecular weight Mn of 11,193 and a weight average molecular weight Mw of 19,050 (in terms of standard polystyrene).

### Synthetic Example 2

125.4 g of propylene glycol monomethyl ether acetate, 5.2 g (0.05 mol) of styrene, 23.7 g (0.275 mol) of methyl acrylate and 24.9 g (0.175 mol) of glycidyl methacrylate were charged into a suitably sized flask having a thermometer, a cold water condenser, a mechanical stirrer, an external heating source, and nitrogen source. The materials were stirred under nitrogen atmosphere until dissolved (about 30 minutes) at room temperature (˜25° C.). Then, the temperature of the flask contents was raised to 75° C. While maintaining the reaction solution at 75° C., 0.78 g (4.75×10⁻³ mol) of azobisisobutyronitrile was introduced. After stirring under nitrogen atmosphere at 75° C. for 20 hours, the temperature was raised to 100° C. After maintaining this temperature for 1 hour, the reaction solution was cooled down to room temperature and the reaction mixture was poured into DI water, yielding, by precipitation, yielding a white polymer solid. The white polymer solid was washed and dried under vacuum at 50° C. yielding 53.1 g (99%). GPC analysis of the resulting polymer showed that it had a number average molecular weight Mn of 22,216 and a weight average molecular weight Mw of 36,300 (in terms of standard polystyrene).

### Synthetic Example 3

242.3 g of propylene glycol monomethyl ether acetate, 25.3 g (0.25 mol) of methyl methacrylate and 35.54 g (0.25 mol) of glycidyl methacrylate were charged into a suitably sized vessel having a thermometer, a cold water condenser, a mechanical stirrer, an external heating source and nitrogen source. The materials were stirred under nitrogen atmosphere until dissolved (about 30 minutes) at room temperature (˜25° C.). Then the temperature of the vessel contents was raised to 75° C. While maintaining the reaction solution at 75° C., 1.56 g (9.5×10⁻³ mol) of azobisisobutyronitrile was introduced. After stirring under nitrogen atmosphere at 75° C. for 20 hours, the temperature of the reaction solution was cooled down to room temperature and the reaction mixture was poured into DI water, yielding, by precipitation, a white polymer solid. The white polymer solid was washed and dried under vacuum at 50° C., yielding 69.0 g (98.4%) of polymer. GPC analysis of the resulting polymer showed that it had a number average molecular weight Mn of 14,238 and a weight average molecular weight Mw of 26,155 (in terms of standard polystyrene).

### Synthetic Example 4

228.68 g of propylene glycol monomethyl ether acetate, 20.8 g (0.20 mol) of styrene, 15.0 g (0.15 mol) of methyl methacrylate and 21.3 g (0.15 mol) of glycidyl methacrylate were charged into a suitably sized flask having a thermometer, a cold water condenser, a mechanical stirrer, an external heating source, and nitrogen source. The materials were stirred under nitrogen atmosphere until dissolved (about 30 minutes) at room temperature (˜25° C.). Then the temperature of the flask contents was raised to 75° C. While maintaining the reaction solution at 75° C., 1.56 g (9.5×10⁻³ mol) of azobisisobutyronitrile was introduced. After stirring under nitrogen atmosphere at 75° C. for 20 hours, the temperature was raised to 100° C. for one hour. The reaction solution was then cooled down to room temperature and the reaction mixture was poured into DI water, yielding, by precipitation, a white polymer solid. The white polymer solid was washed and dried under vacuum at 50° C. yielding 58.6 g (99.8%). GPC analysis of the resulting polymer showed that it had a number average molecular weight Mn of 8117 and a weight average molecular weight Mw of 13,279 (in terms of standard polystyrene).

### Synthetic Example 5

264.2 g of propylene glycol monomethyl ether acetate, 14.6 g of styrene, 21.6 g of 2-hydroxypropyl methacrylate and 29.9 g of glycidyl methacrylate were charged into a suitably sized flask having a thermometer, a cold water condenser, a mechanical stirrer, an external heating source, and nitrogen source. The materials were stirred under nitrogen atmosphere until dissolved (about 30 minutes) at room temperature (˜25° C.). Then, the temperature of the flask contents was raised to 75° C. While maintaining the temperature at 75° C., 1.56 g (9.5×10⁻³ mol) of azobisisobutyronitrile was introduced. After stirring under nitrogen atmosphere at 75° C. for 20 hours, the reaction solution was cooled down to room temperature and the reaction mixture was poured into DI water, yielding, by precipitation, a white polymer solid. The white polymer solid was washed and dried under vacuum at 50° C. yielding 66.0 g (>99%). GPC analysis of the resulting polymer showed that it had a number average molecular weight Mn of 11,942 and a weight average molecular weight Mw of 21,261 (in terms of standard polystyrene).

### Synthetic Example 6

263.1 g of propylene glycol monomethyl ether acetate, 15.62 g (0.15 mol) of styrene, 28.83 g (0.20 mol) of dimethyl maleate and 21.3 g (0.15 mol) of glycidyl methacrylate were charged into a suitably sized flask having a thermometer, a cold water condenser, a mechanical stirrer, an external heating source, and nitrogen source. The materials were stirred under nitrogen atmosphere until dissolved (about 30 minutes) at room temperature (˜25° C.). Then, the temperature of the flask contents was raised to 75° C. While maintaining the temperature at 75° C., 1.56 g (9.5×10⁻³ mol) of azobisisobutyronitrile was introduced. After stirring under nitrogen atmosphere at 75° C. for 20 hours, the temperature was raised to 100° C. After maintaining this temperature for 1 hour, the reaction solution was cooled down to room temperature and the reaction mixture was poured into DI water, yielding, by precipitation, a white polymer solid. The white polymer solid was washed and dried under vacuum at 50° C. yielding 36.2 g (55%). GPC analysis of the resulting polymer showed that it had a number average molecular weight Mn of 5273 and a weight average molecular weight Mw of 8722 (in terms of standard polystyrene).

### Synthetic Example 7

296.7 g of propylene glycol monomethyl ether acetate, 14.58 g (0.14 mol) of styrene, 29.74 g (0.15 mol) of 2-ethylhexyl methacrylate and 29.85 g (0.15 mol) of glycidyl methacrylate were charged into a suitably sized flask having a thermometer, a cold water condenser, a mechanical stirrer, an external heating source, and nitrogen source. The materials were stirred under nitrogen atmosphere until dissolved (about 30 minutes) at room temperature (˜25° C.). Then, the temperature of the flask contents was raised to 75° C. While maintaining the temperature at 75° C., 1.56 g (9.5×10⁻³ mol) of azobisisobutyronitrile was introduced. After stirring under nitrogen atmosphere at 75° C. for 20 hours, the temperature was raised to 100° C. After maintaining this temperature for 1 hour, the reaction solution was cooled down to room temperature and the reaction mixture was poured into DI water, yielding, by precipitation, a white polymer solid. The white polymer solid was washed and dried under vacuum at 50° C. yielding 74.0 g (99%). GPC analysis of the resulting polymer showed that it had a number average molecular weight Mn of 11767 and a weight average molecular weight Mw of 19797 (in terms of standard polystyrene).

### Synthetic Example 8

102.5 g of propylene glycol monomethyl ether acetate, 26.03 g (0.25 mol) of styrene and 35.54 g (0.25 mol) of glycidyl methacrylate were charged into a suitably sized flask having a thermometer, a cold water condenser, a mechanical stirrer, an external heating source, and nitrogen source. The materials were stirred under nitrogen atmosphere until dissolved (about 30 minutes) at room temperature (˜25° C.). Then, the temperature of the flask contents was raised to 75° C. While maintaining the temperature at 75° C., 0.78 g (4.75×10⁻³ mol) of azobisisobutyronitrile was introduced. After stirring under nitrogen atmosphere at 75° C. for 20 hours, the temperature was raised to 100° C. After maintaining this temperature for 1 hour, the reaction solution was cooled down to room temperature and the reaction mixture was poured into DI water, yielding, by precipitation, a white polymer solid. The white polymer solid was washed and dried under vacuum at 50° C. yielding 60.3 g (98%). GPC analysis of the resulting polymer showed that it had a number average molecular weight Mn of 19708 and a weight average molecular weight Mw of 33750 (in terms of standard polystyrene).

### Formulation Example 1

0.25 g of the polymer obtained in Synthetic Example 1, 0.06 g of triethylamine salt of nanofluorobutane sulfonic acid (1 wt % solution in ArF thinner (PGMEA/PGME 70/30 wt/wt)) were dissolved in 2.25 g of ArF thinner (PGMEA/PGME 70/30 wt/wt) to obtain a solution. The solution was heated to 200° C. to cure the polymer and evaporate the solvent. The cured polymer was dried under vacuum at 50° C. The TGA of the sample was measured. Weight loss was found to be 1.4% at 250° C. and 3.8% at 300° C.

### Formulation Example 2

0.206 g of the polymer obtained in Synthetic Example 1, 0.05 g of triethylamine salt of nanofluorobutane sulfonic acid (1 wt % solution in ArF thinner (PGMEA/PGME 70/30 wt/wt)) and 0.053 g of glycidyl end-capped poly(bisphenol A-co-epichlorohydrin), average Mₙ ˜1,075 (available from Sigma-Aldrich) were dissolved in 2.25 g of ArF thinner (PGMEA/PGME 70/30 wt/wt) to obtain a solution. The solution was heated to 200° C. to cure the polymer and evaporate the solvent. The cured polymer was dried under vacuum at 50° C. The TGA of the sample was measured. And the weight loss was found to be 0.81% at 250° C. and 2.5% at 300° C.

### Formulation Example 3

0.25 g of the copolymer obtained in Synthetic Example 3, 0.06 g of triethylamine salt of nanofluorobutane sulfonic acid (1 wt % solution in ArF thinner (PGMEA/PGME 70/30 wt/wt)) were dissolved in 2.25 g of ArF thinner (PGMEA/PGME 70/30 wt/wt) to obtain a solution. The solution was heated to 200° C. to cure the polymer and evaporate the solvent. The cured polymer was dried under vacuum at 50° C. The TGA of the sample was measured. Weight loss was found to be 3.2% at 250° C. and 15.2% at 300° C.

### Formulation Example 4

0.25 g of the terpolymer obtained in Synthetic Example 4, 0.06 g of triethylamine salt of nanofluorobutane sulfonic acid (1 wt % solution in ArF thinner (PGMEA/PGME 70/30 wt/wt)) were dissolved in 2.25 g of ArF thinner (PGMEA/PGME 70/30 wt/wt) to obtain a solution. Then the solution was heated to 200° C. to cure the polymer and evaporate the solvent. The cured polymer was dried under vacuum at 50° C. The TGA of the sample was measured. Weight loss was found to be 2.1% at 250° C. and 6.5% at 300° C.

### Formulation Example 5

0.25 g of the terpolymer obtained in Synthetic Example 8, 0.06 g of triethylamine salt of nanofluorobutane sulfonic acid (1 wt % solution in ArF thinner (PGMEA/PGME 70/30 wt/wt)) were dissolved in 2.25 g of ArF thinner (PGMEA/PGME 70/30 wt/wt) to obtain a solution. Then the solution was heated to 200° C. to cure the polymer and evaporate the solvent. The cured polymer was dried under vacuum at 50° C. The TGA of the sample was measured. Weight loss was found to be 1.6% at 250° C. and 5.6% at 300° C.

### Formulation Example 6

4.5 g of the polymer obtained in Synthetic Example 1, 1.0 g of triethylamine salt of nanofluorobutane sulfonic acid (1 wt % solution in ArF thinner (PGMEA/PGME 70/30 wt/wt)), 0.40 g of FC4430 (1 wt % solution in ArF thinner (PGMEA/PGME 70/30 wt/wt)) and 0.50 g of glycidyl end-capped poly(bisphenol A-co-epichlorohydrin), average Mₙ ˜1,075 (available from Sigma-Aldrich) were dissolved in 45.0 g of ArF thinner (PGMEA/PGME 70/30 wt/wt) to obtain a solution. The solution was filtered through a micro filter made of polyethylene having a pore diameter of 0.05 μm, to prepare a composition solution for a via-filling coating. Refractive index (n) and absorption parameter (k) at a wavelength of 193 nm were measured by spectroscopic ellipsometry. The refractive index (n) was 1.73 and absorption parameter (k) was 0.39.

### Formulation Example 7

4.5 g of the terpolymer obtained in Synthetic Example 2, 1.0 g of triethylamine salt of nanofluorobutane sulfonic acid (1 wt % solution in ArF thinner (PGMEA/PGME 70/30 wt/wt)), 0.40 g of FC4430 (1 wt % solution in ArF thinner (PGMEA/PGME 70/30 wt/wt)) and 0.50 g of glycidyl end-capped poly(bisphenol A-co-epichlorohydrin), average Mₙ ˜1,075 (available from Sigma-Aldrich) were dissolved in 45.0 g of ArF thinner (PGMEA/PGME 70/30 wt/wt) to obtain a solution. The solution was filtered through a micro filter made of polyethylene having a pore diameter of 0.05 μm, to prepare a composition solution for via-filling coating. Refractive index (n) and absorption parameter (k) at a wavelength of 193 nm were measured by spectroscopic ellipsometry. The refractive index (n) was 1.70 and absorption parameter (k) was 0.20.

### Formulation Example 8

4.5 g of the terpolymer obtained in Synthetic Example 4, 1.0 g of triethylamine salt of nanofluorobutane sulfonic acid (1 wt % solution in ArF thinner (PGMEA/PGME 70/30 wt/wt)), 0.40 g of FC4430 (1 wt % solution in ArF thinner (PGMEA/PGME 70/30 wt/wt)) and 0.50 g of glycidyl end-capped poly(bisphenol A-co-epichlorohydrin), average Mₙ ˜1,075 (available from Sigma-Aldrich) were dissolved in 45.0 g of ArF thinner (PGMEA/PGME 70/30 wt/wt) to obtain a solution. The solution was filtered through a micro filter made of polyethylene having a pore diameter of 0.05 μm, to prepare a composition solution for via-filling coating. Refractive index (n) and absorption parameter (k) at a wavelength of 193 nm were measured by spectroscopic ellipsometry. The refractive index (n) was 1.73 and absorption parameter (k) was 0.43.

### Formulation Example 9

4.5 g of the terpolymer obtained in Synthetic Example 5, 1.0 g of triethylamine salt of nanofluorobutane sulfonic acid (1 wt % solution in ArF thinner (PGMEA/PGME 70/30 wt/wt)), 0.40 g of FC4430 (1 wt % solution in ArF thinner (PGMEA/PGME 70/30 wt/wt)) and 0.50 g of glycidyl end-capped poly(bisphenol A-co-epichlorohydrin), average Mₙ ˜1,075 (available from Sigma-Aldrich) were dissolved in 45.0 g of ArF thinner (PGMEA/PGME 70/30 wt/wt) to obtain a solution. The solution was filtered through a micro filter made of polyethylene having a pore diameter of 0.05 μm, to prepare a composition solution for via-filling coating. Refractive index (n) and absorption parameter (k) at a wavelength of 193 nm were measured by spectroscopic ellipsometry. The refractive index (n) was 1.70 and absorption parameter (k) was 0.34.

### Formulation Example 10

4.5 g of the terpolymer obtained in Synthetic Example 6, 1.0 g of triethylamine salt of nanofluorobutane sulfonic acid (1 wt % solution in ArF thinner (PGMEA/PGME 70/30 wt/wt)), 0.40 g of FC4430 (1 wt % solution in ArF thinner (PGMEA/PGME 70/30 wt/wt)) and 0.50 g of glycidyl end-capped poly(bisphenol A-co-epichlorohydrin), average Mₙ ˜1,075 (available from Sigma-Aldrich) were dissolved in 45.0 g of ArF thinner (PGMEA/PGME 70/30 wt/wt) to obtain a solution. The solution was filtered through a micro filter made of polyethylene having a pore diameter of 0.05 μm, to prepare a composition solution for via-filling coating. Refractive index (n) and absorption parameter (k) at a wavelength of 193 nm were measured by spectroscopic ellipsometry. The refractive index (n) was 1.66 and absorption parameter (k) was 0.61.

### Formulation Example 11

4.5 g of the terpolymer obtained in Synthetic Example 7, 1.0 g of triethylamine salt of nanofluorobutane sulfonic acid (1 wt % solution in ArF thinner (PGMEA/PGME 70/30 wt/wt)), 0.40 g of FC4430 (1 wt % solution in ArF thinner (PGMEA/PGME 70/30 wt/wt)) and 0.50 g of glycidyl end-capped poly(bisphenol A-co-epichlorohydrin), average Mₙ ˜1,075 (available from Sigma-Aldrich) were dissolved in 45.0 g of ArF thinner (PGMEA/PGME 70/30 wt/wt) to obtain a solution. The solution was filtered through a micro filter made of polyethylene having a pore diameter of 0.05 μm, to prepare a composition solution for via-filling coating. Refractive index (n) and absorption parameter (k) at a wavelength of 193 nm were measured by spectroscopic ellipsometry. The refractive index (n) was 1.69 and absorption parameter (k) was 0.30.

### Formulation Example 12

4.5 g of the terpolymer obtained in Synthetic Example 8, 1.0 g of triethylamine salt of nanofluorobutane sulfonic acid (1 wt % solution in ArF thinner (PGMEA/PGME 70/30 wt/wt)), 0.40 g of FC4430 (1 wt % solution in ArF thinner (PGMEA/PGME 70/30 wt/wt)) and 0.50 g of glycidyl end-capped poly(bisphenol A-co-epichlorohydrin), average Mₙ ˜1,075 (available from Sigma-Aldrich) were dissolved in 45.0 g of ArF thinner (PGMEA/PGME 70/30 wt/wt) to obtain a solution. The solution was filtered through a micro filter made of polyethylene having a pore diameter of 0.05 μm, to prepare a composition solution for via-filling coating. Refractive index (n) and absorption parameter (k) at a wavelength of 193 nm were measured by spectroscopic ellipsometry. The refractive index (n) was 1.75 and absorption parameter (k) was 0.52.

### Via-Filling Example 1

The composition from Formulation Example 6 was applied over silicon wafer substrates having preformed isolated and dense holes (300, 200, 160, 140, and 130 nm in diameter and 650 nm in depth) by spinning. The coated wafers were then heated on a hot plate at 250° C. for 90 sec to form a 300 nm thick film.

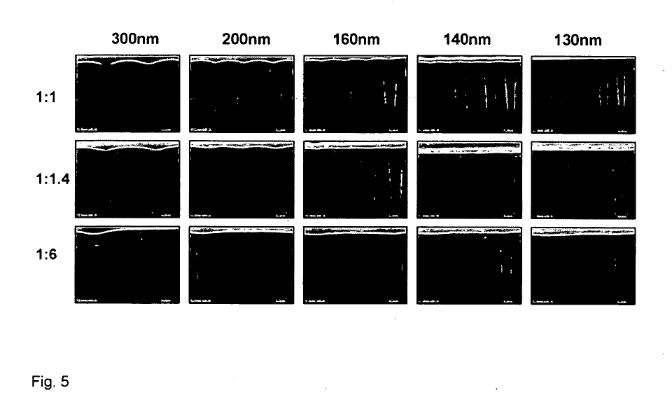

The via-filling performance was evaluated by observing the cross-sectional shape of the obtained substrate using scanning electron microscopy. As seen in FIG. 5, the holes were filled completely and no voids were seen. Iso-dense bias and flat-dense bias data are shown in Table 1. The average iso-dense bias (the difference between top layer film thickness of isolated and dense via) was about 97 nm. The average flat-dense bias (the difference between top layer film thickness of flat and dense via) was about 108 nm.

TABLE 1

| | | | 200 | 160 | 140 | 130 | |
|---|---|---|---|---|---|---|---|
| | | 300 nm | nm | nm | nm | nm | Average |
| Formulation | Dense | 158 | 153 | 156 | 146 | 166 | |
| Example 6 | | | | | | | |
| | Iso | 255 | 251 | 260 | 246 | 251 | |
| FT = 300 nm | flat | 266 | 262 | 266 | 269 | 255 | |
| | iso-dense | 97 | 98 | 104 | 100 | 85 | 96.8 |
| | flat-dense | 108 | 109 | 110 | 123 | 89 | 107.8 |

### Via-Filling Example 2

The composition from Formulation Example 7 was applied over silicon wafer substrates having preformed isolated and dense holes (300, 200, 160, 140, and 130 nm in diameter and 650 nm in depth) by spinning. The coated wafers were then heated on a hot plate at 250° C. for 90 sec to form a 300 nm thick film.

The via-filling performance was evaluated by observing the cross-sectional shape of the obtained substrate using scanning electron microscopy. The holes were filled completely and no voids were seen when baked at 250° C. Iso-dense bias and flat-dense bias data are shown in Table 2. The average iso-dense bias (the difference between top layer film thickness of isolated and dense via) was about 102 nm. The average flat-dense bias (the difference between top layer film thickness of flat and dense via) was about 97 nm.

TABLE 2

| | | 300 | 200 | 160 | 140 | | |
|---|---|---|---|---|---|---|---|
| | | nm | nm | nm | nm | 130 nm | Average |
| Formulation | Dense | 131 | 109 | 124 | 142 | 160 | |
| Example 7 | | | | | | | |
| | Iso | 255 | 238 | 238 | 209 | 235 | |
| FT = 300 nm | flat | 246 | 209 | 209 | 247 | 242 | |
| | iso-dense | 124 | 129 | 114 | 67 | 75 | 101.8 |
| | flat-dense | 115 | 100 | 85 | 105 | 82 | 97.4 |

### Via-Filling Example 3

The composition from Formulation Example 8 was applied over silicon wafer substrates having preformed isolated and dense holes (300, 200, 160, 140, and 130 nm in diameter and 650 nm in depth) by spinning. The coated wafers were then heated on a hot plate at 250° C. for 90 sec to form a 300 nm thick film.

The via-filling performance was evaluated by observing the cross-sectional shape of the obtained substrate using scanning electron microscopy. The holes were filled completely and no voids were seen when baked at 250° C. The average iso-dense bias (the difference between top layer film thickness of isolated and dense via) was about 67 nm. The average flat-dense bias (the difference between top layer film thickness of flat and dense via) was about 73 nm.

### Via-Filling Example 4

The composition from Formulation Example 9 was applied over silicon wafer substrates having preformed isolated and dense holes (300, 200, 160, 140, and 130 nm in diameter and 650 nm in depth) by spinning. The coated wafers were then heated on a hot plate at 250° C. for 90 sec to form a 300 nm thick film.

The via-filling performance was evaluated by observing the cross-sectional shape of the obtained substrate using scanning electron microscopy. The holes were filled completely and no voids were seen when baked at 250° C. The average iso-dense bias (the difference between top layer film thickness of isolated and dense via) was about 93 nm. The average flat-dense bias (the difference between top layer film thickness of flat and dense via) was about 100 nm.

### Via-Filling Example 5

The composition from Formulation Example 10 was applied over silicon wafer substrates having preformed isolated and dense holes (300, 200, 160, 140, and 130 nm in diameter and 650 nm in depth) by spinning. The coated wafers were then heated on a hot plate at 250° C. for 90 sec to form a 300 nm thick film.

The via-filling performance was evaluated by observing the cross-sectional shape of the obtained substrate using scanning electron microscopy. The holes were filled completely and no voids were seen when baked at 250° C. The average iso-dense bias (the difference between top layer film thickness of isolated and dense via) was about 142 nm. The average flat-dense bias (the difference between top layer film thickness of flat and dense via) was about 150 nm.

### Via-Filling Example 6

The composition from Formulation Example 11 was applied over silicon wafer substrates having preformed isolated and dense holes (300, 200, 160, 140, and 130 nm in diameter and 650 nm in depth) by spinning. The coated wafers were then heated on a hot plate at 250° C. for 90 sec to form a 300 nm thick film.

The via-filling performance was evaluated by observing the cross-sectional shape of the obtained substrate using scanning electron microscopy. The holes were filled completely and no voids were seen when baked at 250° C. The average iso-dense bias (the difference between top layer film thickness of isolated and dense via) was about 77 nm. The average flat-dense bias (the difference between top layer film thickness of flat and dense via) was about 81 nm.

### Via-Filling Example 7

The composition from Formulation Example 12 was applied over silicon wafer substrates having preformed isolated and dense holes (300, 200, 160, 140, and 130 nm in diameter and 650 nm in depth) by spinning. The coated wafers were then heated on a hot plate at 250° C. for 90 sec to form a 300 nm thick film.

The via-filling performance was evaluated by observing the cross-sectional shape of the obtained substrate using scanning electron microscopy. The holes were filled completely and no voids were seen when baked at 250° C. The average iso-dense bias (the difference between top layer film thickness of isolated and dense via) was about 81 nm. The average flat-dense bias (the difference between top layer film thickness of flat and dense via) was about 79 nm.

The foregoing description of the invention illustrates and describes the present invention. Additionally, the disclosure shows and describes only the preferred embodiments of the invention but, as mentioned above, it is to be understood that the invention is capable of use in various other combinations, modifications, and environments and is capable of changes or modifications within the scope of the inventive concept as expressed herein, commensurate with the above teachings and/or the skill or knowledge of the relevant art. The embodiments described hereinabove are further intended to explain best modes known of practicing the invention and to enable others skilled in the art to utilize the invention in such, or other, embodiments and with the various modifications required by the particular applications or uses of the invention. Accordingly, the description is not intended to limit the invention to the form disclosed herein. Also, it is intended that the appended claims be construed to include alternative embodiments.

1. A gap fill material composition comprising:
a polymer having at least one repeating unit of formula (3) and, optionally, one or more repeating units selected from formula (1), formula (2), and/or mixtures thereof 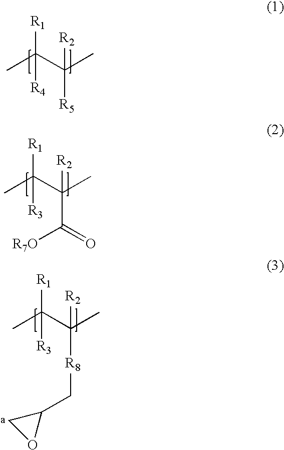
where each of R₁, R₂ and R₄ are individually selected from hydrogen, halogen, cyano, unsubstituted or substituted alkyl, or unsubstituted or substituted cycloalkyl, R₃ is selected from hydrogen, unsubstituted or substituted alkyl, or —C(═O)—O—R₆, R₅ is unsubstituted or substituted aryl, unsubstituted or substituted aralkyl, —C(═O)—O—R₆, —O—R₆, where R₆ is unsubstituted or substituted alkyl, unsubstituted or substituted cycloalkyl, unsubstituted or substituted aryl, or unsubstituted or substituted aralkyl, or R₄ and R₅ together with the carbon atoms to which they are attached form 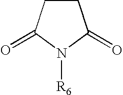
where R₆ is as defined above, R₇ is unsubstituted or substituted alkyl, unsubstituted or substituted cycloalkyl, unsubstituted or substituted aryl, unsubstituted or substituted aralkyl, -(unsubstituted or substituted alkylene)-O-(unsubstituted or substituted aryl), -(unsubstituted or substituted alkylene)-O-(unsubstituted or substituted alkyl), and R₈ is a linking group selected from —C(═O)—O—, —O—, —(CH₂)ₕ—O—, —O—(CH₂)ₕ—, —(CH₂)ₕ—, -(unsubstituted or substituted aryl)-O—, -(unsubstituted or substituted aryl)-, —O-(unsubstituted or substituted aryl)-, or R₈ and the carbon atom identified as ‘a’ together form a cycloaliphatic ring to which the cyclic ether is fused, and h is 1 to 5;
optionally, an epoxy resin having a number average molecular weight Mₙ ranging from about 500 to about 12,000; and
a thermal acid generator.

2. The gap fill material of claim 1 wherein the polymer does not contain repeating units of formula (1) or formula (2).

3. The gap fill material of claim 1 wherein the polymer contains one or more repeating units of formula (1) and does not contain the repeating unit of formula (2).

4. The gap fill material of claim 1 wherein the polymer contains one or more repeating units of formula (2) and does not contain the repeating unit of formula (1).

5. The gap fill material of claim 1 wherein the polymer contains one or more repeating units of formula (1) and one or more repeating units of formula (2).

6. The gap fill material of claim 5 wherein the repeating unit of formula (1) is present in an amount of about 10 to about 40 mol %, the repeating unit of formula (2) is present in an amount of about 10 to about 60 mol %, and the repeating unit of formula (3) is present in an amount of about 20 to about 80 mol %.

7. The gap fill material of claim 5 wherein the repeating unit of formula (1) is present in an amount of about 10 to about 30 mol %, the repeating unit of formula (2) is present in an amount of about 30 to about 60 mol %, and the repeating unit of formula (3) is present in an amount of about 30 to about 50 mol %.

8. The gap fill material of claim 1 where the epoxy resin is present.

9. The gap fill material of claim 7 wherein the epoxy resin is present in an amount of from about 0.1 to about 30 wt % of the composition.

10. The gap fill material of claim 8 where the epoxy resin is selected from polyglycidyl ethers of polyhydric phenols, epoxy novolacs or similar glycidated polyphenolic resins, polyglycidyl ethers of glycols or polyglycols, and polyglycidyl esters of polycarboxylic acids.

11. The gap fill material of claim 8 wherein the epoxy resin is selected from polyglycidyl ethers of polyhydric phenols.

12. The gap fill material of claim 8 where the epoxy resin is selected from 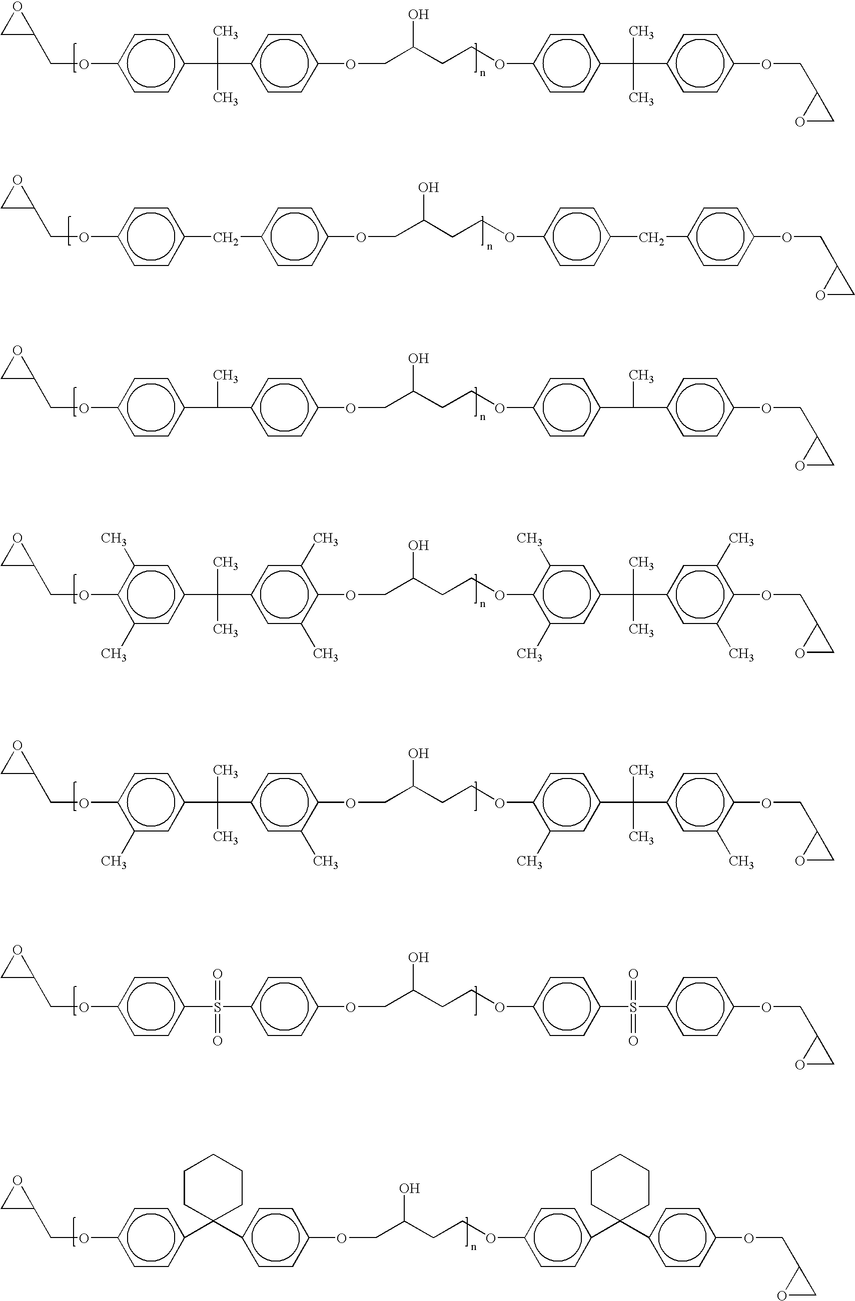 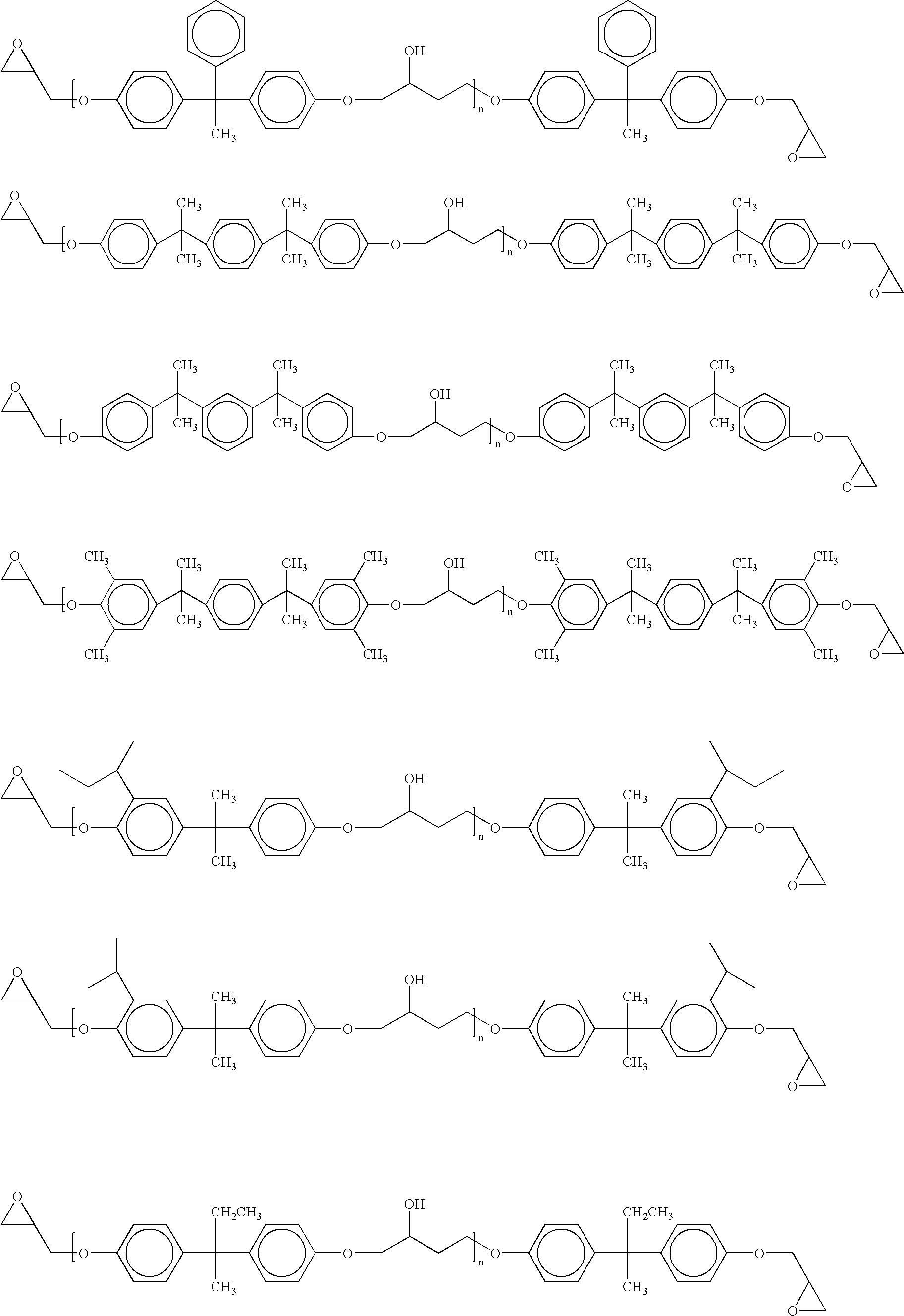
where n is about 2 to about 45.

13. A gap fill material composition comprising:
a polymer having at least one repeating unit of formula (3) and one or more repeating units selected from formula (1), formula (2), and/or mixtures thereof 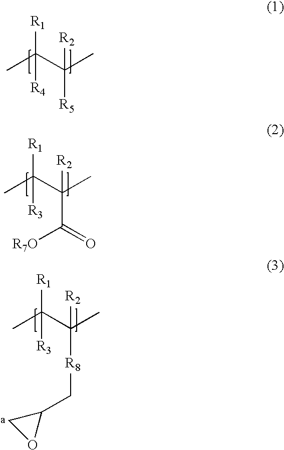
where each of R₁, R₂ and R₄ are individually selected from hydrogen, halogen, cyano, unsubstituted or substituted alkyl, or unsubstituted or substituted cycloalkyl, R₃ is selected from hydrogen, unsubstituted or substituted alkyl, or —C(═O)—O—R₆, R₅ is unsubstituted or substituted aryl, unsubstituted or substituted aralkyl, —C(═O)—O—R₆, —O—R₆, where R₆ is unsubstituted or substituted alkyl, unsubstituted or substituted cycloalkyl, unsubstituted or substituted aryl, or unsubstituted or substituted aralkyl, or R₄ and R₅ together with the carbon atoms to which they are attached form 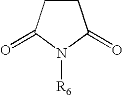
where R₆ is as defined above, R₇ is unsubstituted or substituted alkyl, unsubstituted or substituted cycloalkyl, unsubstituted or substituted aryl, unsubstituted or substituted aralkyl, -(unsubstituted or substituted alkylene)-O-(unsubstituted or substituted aryl), -(unsubstituted or substituted alkylene)-O-(unsubstituted or substituted alkyl), and R₈ is a linking group selected from —C(═O)—O—, —O—, —(CH₂)ₕ—O—, —O—(CH₂)ₕ—, —(CH₂)ₕ—, -(unsubstituted or substituted aryl)-O—, -(unsubstituted or substituted aryl)-, —O-(unsubstituted or substituted aryl)-, or R₈ and the carbon atom identified as ‘a’ together form a cycloaliphatic ring to which the cyclic ether is fused, and h is 1 to 5;
an epoxy resin having a number average molecular weight Mₙ ranging from about 500 to about 12,000; and
a thermal acid generator.

14. The gap fill material of claim 13 wherein the repeating unit of formula (1) is present in an amount of about 10 to about 40 mol %, the repeating unit of formula (2) is present in an amount of about 10 to about 60 mol %, and the repeating unit of formula (3) is present in an amount of about 20 to about 80 mol %.

15. The gap fill material of claim 13 wherein the repeating unit of formula (1) is present in an amount of about 10 to about 30 mol %, the repeating unit of formula (2) is present in an amount of about 30 to about 60 mol %, and the repeating unit of formula (3) is present in an amount of about 30 to about 50 mol %.

16. The gap fill material of claim 13 where the epoxy resin is selected from polyglycidyl ethers of polyhydric phenols, epoxy novolacs or similar glycidated polyphenolic resins, polyglycidyl ethers of glycols or polyglycols, and polyglycidyl esters of polycarboxylic acids.

17. The gap fill material of claim 13 wherein the epoxy resin is selected from polyglycidyl ethers of polyhydric phenols.

18. The gap fill material of claim 13 where the epoxy resin is selected from 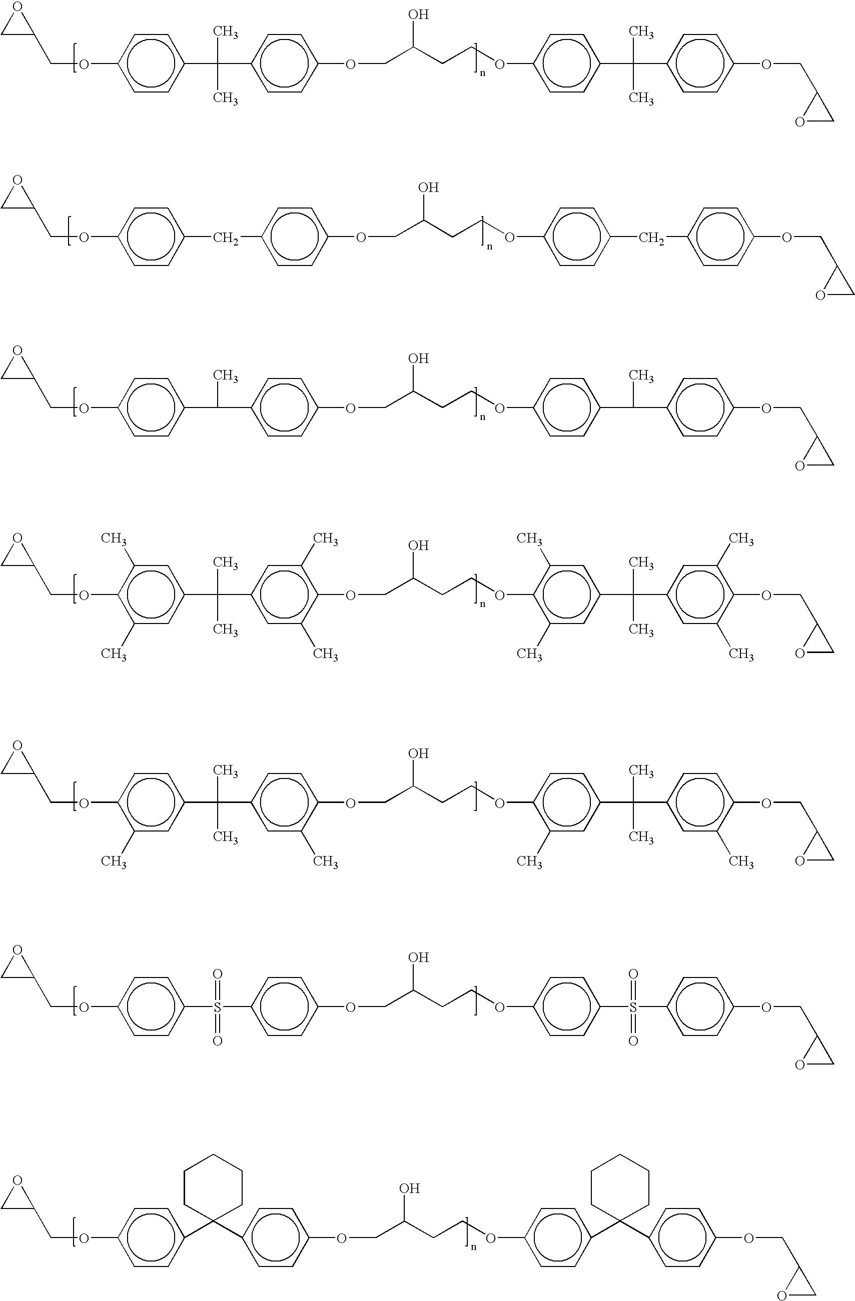 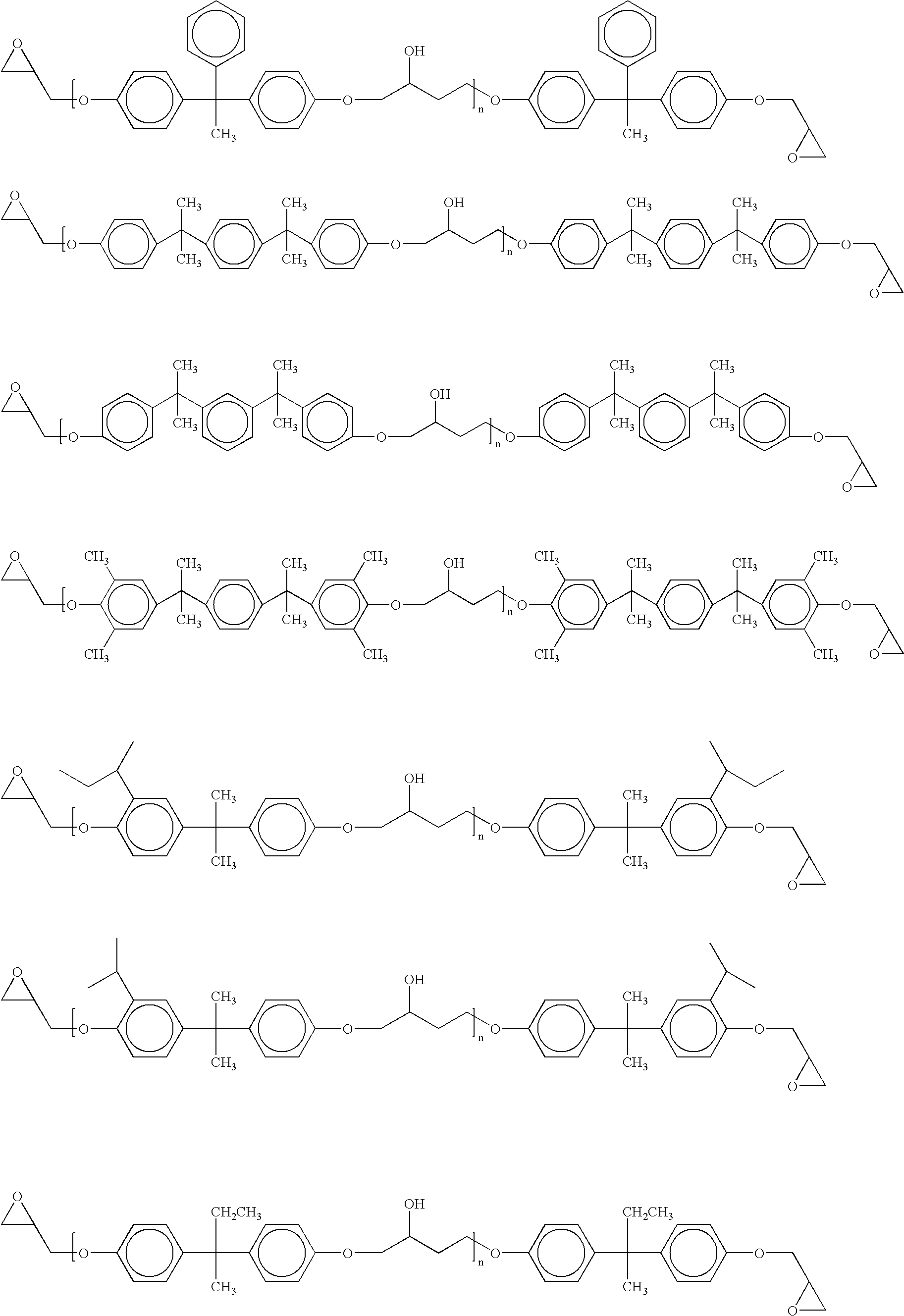
where n is about 2 to about 45.

19. A polymer having repeating units of 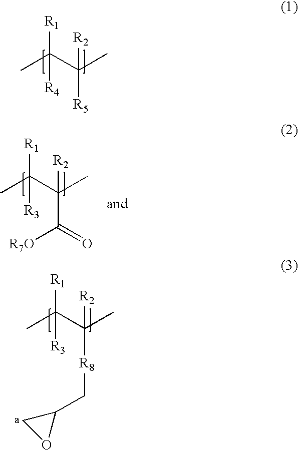
where each of R₁, R₂ and R₄ are individually selected from hydrogen, halogen, cyano, unsubstituted or substituted alkyl, or unsubstituted or substituted cycloalkyl, R₃ is selected from hydrogen, unsubstituted or substituted alkyl, or —C(═O)—O—R₆, R₅ is unsubstituted or substituted aryl, unsubstituted or substituted aralkyl, —C(═O)—O—R₆, —O—R₆, where R₆ is unsubstituted or substituted alkyl, unsubstituted or substituted cycloalkyl, unsubstituted or substituted aryl, or unsubstituted or substituted aralkyl, or R₄ and R₅ together with the carbon atoms to which they are attached form 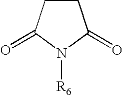
where R₆ is as defined above, R₇ is unsubstituted or substituted alkyl, unsubstituted or substituted cycloalkyl, unsubstituted or substituted aryl, unsubstituted or substituted aralkyl, -(unsubstituted or substituted alkylene)-O-(unsubstituted or substituted aryl), -(unsubstituted or substituted alkylene)-O-(unsubstituted or substituted alkyl), and R₈ is a linking group selected from —C(═O)—O—, —O—, —(CH₂)ₕ—O—, —O—(CH₂)ₕ—, —(CH₂)ₕ—, -(unsubstituted or substituted aryl)-O—, -(unsubstituted or substituted aryl)-, —O-(unsubstituted or substituted aryl)-, or R₈ and the carbon atom identified as ‘a’ together form a cycloaliphatic ring to which the cyclic ether is fused, h is 1 to 5, the repeating unit of formula (1) present in an amount of about 10 to about 40 mol %, the repeating unit of formula (2) present in an amount of about 10 to about 60 mol %, and the repeating unit of formula (3) present in an amount of about 20 to about 80 mol %.

20. The polymer of claim 19 wherein the repeating unit of formula (1) is present in an amount of about 10 to about 30 mol %, the repeating unit of formula (2) is present in an amount of about 30 to about 60 mol %, and the repeating unit of formula (3) is present in an amount of about 30 to about 50 mol %.

21. A process for manufacturing a semiconductor device comprising coating the gap fill material forming composition according to claim 1 on a semiconductor substrate having a hole with aspect ratio shown in height/diameter of 1 or more and baking it.

22. A method for forming photoresist pattern for use in manufacture of semiconductor device, comprising coating the gap fill material forming composition according to claim 1 on a semiconductor substrate having a hole with aspect ratio shown in height/diameter of 1 or more, baking it to form a gap fill material, forming a photoresist layer on the gap fill material, exposing the semiconductor substrate covered with the gap fill material and the photoresist layer to light, and developing the photoresist layer after the exposure to light.

23. The method for forming photoresist pattern according to claim 22, further comprising a step of forming an anti-reflective coating before or after the step of forming the gap fill material on the semiconductor substrate.
